(19) United States
(12) Patent Application Publication
(10) Pub. No.: US 2014/0182644 A1
(43) Pub. Date: Jul. 3, 2014

(54) STRUCTURES AND METHODS FOR MULTI-LEG PACKAGE THERMOELECTRIC DEVICES

(71) Applicant: Alphabet Energy, Inc., Hayward, CA (US)

(72) Inventors: Mario Aguirre, Livermore, CA (US); Adam Lorimer, Walnut Creek, CA (US); Sasi Bhushan Beera, Fremont, CA (US); Sravan Kumar Sura, Fremont, CA (US); Matthew L. Scullin, San Francisco, CA (US); Sylvain Muckenhirn, Santa Barbara, CA (US); Douglas Crane, Richmond, CA (US)

(73) Assignee: Alphabet Energy, Inc., Hayward, CA (US)

(21) Appl. No.: 14/053,452

(22) Filed: Oct. 14, 2013

Related U.S. Application Data
(60) Provisional application No. 61/713,767, filed on Oct. 15, 2012.
(60) Provisional application No. 61/802,097, filed on Mar. 15, 2013.

(51) Int. Cl. H01L 35/32; H01L 35/34

(52) U.S. Cl. CPC H01L 35/325; H01L 35/34
USPC 136/200; 136/201

(57) ABSTRACT

Thermoelectric device with a multi-leg package and method thereof. The thermoelectric device includes a first ceramic base structure including a first surface and a second surface, and a first plurality of pads including one or more first materials thermally and electrically conductive. The first plurality of pads are attached to the first surface. Additionally, the thermoelectric device includes a second plurality of pads including the one or more first materials. The second plurality of pads are attached to the second surface and arranged in a mirror image with the first plurality of pads. Moreover, the thermoelectric device includes a plurality of thermoelectric legs attached to the first plurality of pads respectively. Each pad of the first plurality of pads is attached to at least two first thermoelectric legs of the plurality of thermoelectric legs.

### 1. CROSS-REFERENCES TO RELATED APPLICATIONS

This application claims priority to U.S. Provisional Application No. 61/713,767, filed Oct. 15, 2012, and U.S. Provisional Application No. 61/802,097, filed Mar. 15, 2013, commonly assigned and incorporated by reference herein for all purposes.

Additionally, this application is related to U.S. patent application Ser. Nos. 13/299,179, 13/308,945, 13/331,768, and 13/364,176, which are incorporated by reference herein for all purposes.

### 2. BACKGROUND OF THE INVENTION

The present invention is directed to thermoelectric devices. More particularly, the invention provides structures and methods for forming a multi-leg package (MLP) assembly. Merely by way of example, the invention has been applied to packaging a plurality of thermoelectric legs for the manufacture of a thermoelectric module. However, it would be recognized that the invention has a much broader range of applicability.

Conventional thermoelectric devices are often packaged using a plurality of thermoelectric (TE) legs arranged in multiple serial-chain configurations on a base structure. Each of the plurality of thermoelectric legs is made by either p-type or n-type thermoelectric material. The thermoelectric material, either p-type or n-type, is usually selected to be a semiconductor characterized by high electrical conductivity and high thermal resistivity. For example, as a pair, a p-type leg is coupled to an n-type leg via a conductor in the serial-chain configuration. In another example, one conductor is coupled to one end region of a leg and another conductor is coupled to another end region of the leg.

When the thermoelectric device is applied with a bias voltage across the top and bottom regions using two electrodes, a temperature difference is generated so that the thermoelectric device can be used as a refrigeration (e.g., Peltier) device. When the thermoelectric device is subjected to a thermal gradient with conductors at first end regions of the legs being attached to a cold side of the junction and conductors at second end regions of the legs being in contact with a hot side of the junction, the thermoelectric device is able to generate electrical voltage across the junction as an energy conversion (e.g., Seebeck) device.

FIG. 1 is a simplified diagram showing a conventional thermoelectric leg. As shown, the thermoelectric (TE) leg 100 includes a thermoelectric material 101 made into a bulk-sized structure with about 1-2 millimeters or more in length and a few millimeters or less in lateral dimensions. For example, the thermoelectric material 101 is pre-fabricated from a large wafer-sized material using planar semiconductor processing techniques. Afterwards, the pre-fabricated large wafer-sized thermoelectric material is subjected to a series of cutting processes and is then transformed into multiple units with desired shapes and dimensions as mentioned above. Of course, the dimensions can be varied depending on applications. In another example, the illustration of the leg 100 in FIG. 1 is not drawn to scale with its length exaggerated compared to its lateral dimensions.

The thermoelectric material 101 is characterized by its high electrical conductivity. For example, the thermoelectric material 101 is a semiconductor (e.g., a single-element semiconductor, a compound semiconductor, or a composite semiconductor), doped to n-type or p-type (e.g., with electrical impurities to adjust the resistivity of the semiconductor to between approximately 0.00001 Ω-m and 10 Ω-m). The thermoelectric material 101 is also characterized by its high thermal resistance. The high thermal resistance can be achieved through material selection and/or structural reconfiguration. For example, exotic compound materials such as bismuth telluride (Bi₂Te₃) or lead telluride (PbTe) are selected for their thermoelectric functionality by having a low lattice thermal conductivity of about 1.20 W/(m·K). Other applicable thermoelectric materials such as Mg₂Si, MnSi₂, or PbTe can also be used. In another example, the bulk-sized structure for the thermoelectric material 101 includes a network of nanowires without substantially aligned parallel along a length direction of the structure. The bulk-sized structure for the thermoelectric material 101 is intended for forming a leg structure that has a thermal resistance as large as possible along its length while maintaining a good electrical conduction through the structure.

As shown in FIG. 1, the TE leg 100 includes end electrodes 111 and 113 respectively bonded to two end regions of the bulk-sized structure for the thermoelectric material 101. For example, each of the end electrodes 111 and 113 includes a metalized layer and/or a conductive material. In another example, the end electrodes 111 and 113 are used as electrical leads for conducting an electrical current generated from thermal gradient via Seebeck effect and also as thermal contacts for attaching with a hot side and a cold side of a thermal junction respectively.

The end electrodes 111 and 113 can be formed by metallization of the end regions of the bulk-sized structure for the thermoelectric material 101 and attachment of one or more conductor materials to the metalized end regions (e.g., the metalized layers). For example, the one or more conductive materials are applied by physical deposition or plating. In another example, thermal annealing and polishing processes are also included to enhance physical coverage overlying the metalized layers and to form smoother surfaces of the end electrodes 111 and 113. One of the two end electrodes 111 and 113 is bonded to a hot-side contact when the TE leg 100 is assembled as one unit in a serial-chain configuration of a thermoelectric device while the other one of the two end electrodes 111 and 113 is bonded to a cold-side contact of the thermoelectric device. Both the hot-side contact and the cold-side contact are directly associated with the same thermal junction applied by the thermoelectric device.

FIG. 2 is a simplified diagram showing a conventional n-type thermoelectric leg and a conventional p-type thermoelectric leg. For example, the n-type TE leg 210 is a thermoelectric (TE) leg 100, and the p-type TE leg 220 is another thermoelectric (TE) leg 100. In another example, the n-type TE leg 210 includes an n-type thermoelectric material 201 and end electrodes 211 and 213, and the p-type TE leg 220 includes a p-type thermoelectric material 202 and end electrodes 221 and 223.

The end electrodes 211 and 213 for the n-type TE leg 210 and the end electrodes 221 and 223 for the p-type TE leg 220 do not have to be formed with different materials with different processes specifically for n-type or p-type characteristics. Different bonding materials and/or different bonding processes are used to form an end electrode of a particular type of TE leg. For example, the bonding and/or brazing material is selected to make the end electrode specifically suited for accommodating different thermal stress depending on whether the end electrode is against with a cold-side contact or a hot-side contact when the TE leg is packaged into a thermoelectric device.

The energy conversion efficiency of thermoelectric devices can be measured by a so-called thermal power density or “thermoelectric figure of merit” ZT. ZT is equal to TS² σ/k where T is the temperature, S is the Seebeck coefficient, σ is the electrical conductivity, and k is the thermal conductivity of the thermoelectric material. In order to drive up the value of ZT of thermoelectric devices utilizing the Seebeck effect, searching for high performance thermoelectric materials and developing low cost manufacturing processes are major concerns. Additionally, there are also needs for improved techniques of packaging thermoelectric devices. For example, mounting a plurality of thermoelectric legs in a serial-chain configuration needs a base structure that can handle high thermal stress induced by the ultra-high temperature gradient, especially for TE legs with relative high aspect ratio in their physical structures and/or TE legs formed by a TE material having a thermal expansion coefficient that is different from the thermal expansion coefficient of a heat sink material. In another example, reliable end-electrodes need to be developed for each TE leg, where the end-electrodes are in contact with both the thermoelectric material and the heat sink material.

Conventional thermoelectric modules and/or devices often include an alumina or similar ceramic as a substrate base plate on both sides of multiple thermoelectric legs connected in series. For example, a conventional thermoelectric device is 40-mm-long by 40-mm-wide by 3-mm-thick, and the conventional thermoelectric device includes two ceramic plates with a low coefficient of thermal expansion (CTE) (e.g., CTE being lower than 10×10⁻⁶/° C., such as CTE equal to 4×10⁻⁶/° C. at the room temperature) and also includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are sandwiched between the two ceramic plates and bonded to the two ceramic plates via thin metal shunts (e.g., CTE of the thin metal shunts being equal to 16×10⁻⁶/° C. at the room temperature) for electrical connection of the legs. In another example, these conventional modules and/or devices are based on bismuth telluride Peltier cooling technology, and so are optimized to work with manufacturing tooling that is used to manufacture Peltier coolers. In yet another example, these conventional modules and/or devices that are based on bismuth telluride Peltier cooling technology usually include materials and structures not intended to withstand high temperatures or large temperature gradients because these Peltier coolers are designed to maintain temperature gradients smaller than 50 degrees for temperatures that are below 150° C. These conventional alumina base plates, as well as the soldering and/or brazing materials, electrical shunts, joining and interface layers, and/or associated manufacturing processes are often designed to be optimal for these Peltier products under the above stated conditions. They usually do not offer the ability to operate at temperatures above 250° C. (especially in the case of bismuth telluride devices), nor can they withstand large temperature gradients that are larger than 200 degrees without mechanical failures that can result in electrical discontinuity.

Hence, it is highly desirable to improve packaging techniques that take into consideration the thermal environment in which a thermoelectric device operates.

### 3. BRIEF SUMMARY OF THE INVENTION

The present invention is directed to thermoelectric devices. More particularly, the invention provides structures and methods for forming a multi-leg package (MLP) assembly. Merely by way of example, the invention has been applied to packaging a plurality of thermoelectric legs for the manufacture of a thermoelectric module. However, it would be recognized that the invention has a much broader range of applicability.

According to one embodiment, a thermoelectric device with a multi-leg package includes a first ceramic base structure including a first surface and a second surface, and a first plurality of pads including one or more first materials thermally and electrically conductive. The first plurality of pads are attached to the first surface. Additionally, the thermoelectric device includes a second plurality of pads including the one or more first materials. The second plurality of pads are attached to the second surface and arranged in a mirror image with the first plurality of pads. Moreover, the thermoelectric device includes a plurality of thermoelectric legs attached to the first plurality of pads respectively. Each pad of the first plurality of pads is attached to at least two first thermoelectric legs of the plurality of thermoelectric legs. Also, the thermoelectric device includes a first plurality of sheet conductors attached to the plurality of thermoelectric legs respectively and including one or more second materials thermally and electrically conductive. Each sheet conductor of the first plurality of sheet conductors is attached to at least two second thermoelectric legs of the plurality of thermoelectric legs. The first plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

According to yet another embodiment, a thermoelectric device with a multi-leg package includes a plurality of pads including one or more first materials thermally and electrically conductive. The plurality of pads are parts of a first metal lead frame without any metal tab linking the plurality of pads. Additionally, the thermoelectric device includes a plurality of thermoelectric legs attached to the plurality of pads respectively. Each pad of the plurality of pads is attached to at least two first thermoelectric legs of the plurality of thermoelectric legs. Moreover, the thermoelectric device includes a first plurality of sheet conductors attached to the plurality of thermoelectric legs respectively and including one or more second materials thermally and electrically conductive. Each sheet conductor of the first plurality of sheet conductors is attached to at least two second thermoelectric legs of the plurality of thermoelectric legs. The plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

According to yet another embodiment, a method for making a thermoelectric device with a multi-leg package includes providing a first ceramic base structure including a first surface and a second surface. The first surface is attached to a first plurality of pads, the second surface is attached to a second plurality of pads arranged in a mirror image with the first plurality of pads, and both the first plurality of pads and the second plurality of pads include one or more first materials thermally and electrically conductive. Additionally, the method includes attaching a plurality of thermoelectric legs to the first plurality of pads respectively. Each pad of the first plurality of pads is attached to at least two first thermoelectric legs of the plurality of thermoelectric legs. Additionally, the method includes attaching a first plurality of sheet conductors to the plurality of thermoelectric legs respectively. The first plurality of sheet conductors include one or more second materials thermally and electrically conductive, and each sheet conductor of the first plurality of sheet conductors is attached to at least two second thermoelectric legs of the plurality of thermoelectric legs. The first plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

According to yet another embodiment, a method for making a thermoelectric device with a multi-leg package includes providing a plurality of pads including one or more first materials thermally and electrically conductive. The plurality of pads are parts of a first metal lead frame without any metal tab linking the plurality of pads. Additionally, the method includes attaching a plurality of thermoelectric legs to the plurality of pads respectively. Each pad of the plurality of pads is attached to at least two first thermoelectric legs of the plurality of thermoelectric legs. Moreover, the method includes attaching a first plurality of sheet conductors to the plurality of thermoelectric legs respectively and including one or more second materials thermally and electrically conductive. Each sheet conductor of the first plurality of sheet conductors is attached to at least two second thermoelectric legs of the plurality of thermoelectric legs. The plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

Depending upon the embodiment, one or more benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIG. 1 is a simplified diagram showing a conventional thermoelectric leg.

FIG. 2 is a simplified diagram showing a conventional n-type thermoelectric leg and a conventional p-type thermoelectric leg.

FIG. 3 is a simplified diagram showing bulk-sized thermoelectric legs according to certain embodiments.

FIG. 4A is a simplified diagram showing a thermoelectric unicouple with a stress-relief conductive shunt material for assembly of a thermoelectric device according to one embodiment.

FIG. 4B is a simplified diagram showing the conductive shunt material for forming an electric lead of a thermoelectric device according to one embodiment.

FIG. 5 is a simplified diagram showing a series of thermoelectric unicouples on a base structure for fabrication of a thermoelectric device according to one embodiment of the present invention.

FIG. 6 is a simplified diagram showing a thermoelectric device including the series of thermoelectric unicouples on the base structure according to one embodiment of the present invention.

FIG. 7 is a simplified diagram showing a method for assembling a multi-leg package (MLP) as a thermoelectric device including the series of thermoelectric unicouples on the base structure according to one embodiment of the present invention.

FIGS. 8A-8C are simplified diagrams showing views of certain components of the multi-leg package (MLP) assembled as shown in FIG. 7 according to certain embodiments of the present invention.

FIG. 9 is a simplified diagram showing certain components of the multi-leg package (MLP) as shown in FIG. 6, FIG. 7, and/or FIG. 8 according to certain embodiments of the present invention.

FIG. 10 is a simplified diagram showing a polyimide lead frame as part of the multi-leg package (MLP) as shown in FIG. 6, FIG. 7, FIG. 8, and/or FIG. 9 according to one embodiment of the present invention.

FIG. 11 is a simplified diagram showing a method of making certain components of the multi-leg package (MLP) as shown in FIG. 6, FIG. 7, FIGS. 8A-8C, and/or FIG. 9 according to one embodiment of the present invention.

FIG. 12 is a simplified diagram showing a method of making certain components of the multi-leg package (MLP) as shown in FIG. 6, FIG. 7, FIGS. 8A-8C, and/or FIG. 9 according to another embodiment of the present invention.

FIG. 13 is a simplified diagram showing a method of making certain components of the multi-leg package (MLP) as shown in FIG. 6, FIG. 7, FIGS. 8A-8C, and/or FIG. 9 according to yet another embodiment of the present invention.

FIG. 14 is a simplified diagram showing a method of making certain components of the multi-leg package (MLP) as shown in FIG. 6, FIG. 7, FIGS. 8A-8C, and/or FIG. 9 according to yet another embodiment of the present invention.

FIG. 15 is a simplified diagram showing a method of making certain components of the multi-leg package (MLP) as shown in FIG. 6, FIG. 7, FIGS. 8A-8C, and/or FIG. 9 according to yet another embodiment of the present invention.

FIG. 16 is a simplified diagram showing certain components of a multi-leg package (MLP) according to another embodiment of the present invention.

FIG. 17 is a simplified diagram showing certain components of a multi-leg package (MLP) according to yet another embodiment of the present invention.

FIG. 18 is a simplified diagram showing certain components of a multi-leg package (MLP) according to yet another embodiment of the present invention.

FIG. 19 is a simplified diagram showing certain components of a multi-leg package (MLP) according to yet another embodiment of the present invention.

FIGS. 20A and 20B are simplified diagrams showing simulation results of the conventional thermoelectric device for Example 1.

FIGS. 21A and 21B are simplified diagrams showing simulation results of thermoelectric devices for Examples 2 and 3 according to some embodiments of the present invention.

FIGS. 22A and 22B are simplified diagrams showing simulation results of the thermoelectric device for Example 4 according to one embodiment of the present invention.

FIG. 23 is a simplified diagram showing simulation results of thermoelectric devices for Examples 5 and 6 according to some embodiments of the present invention.

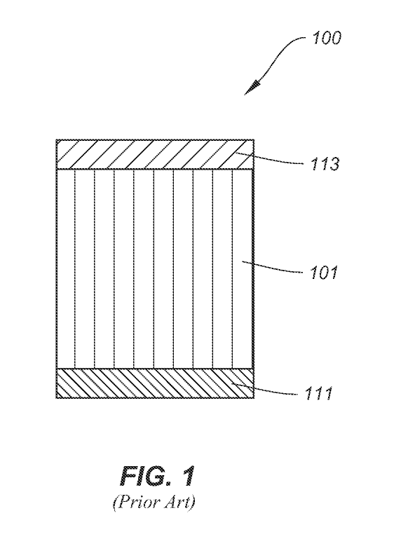

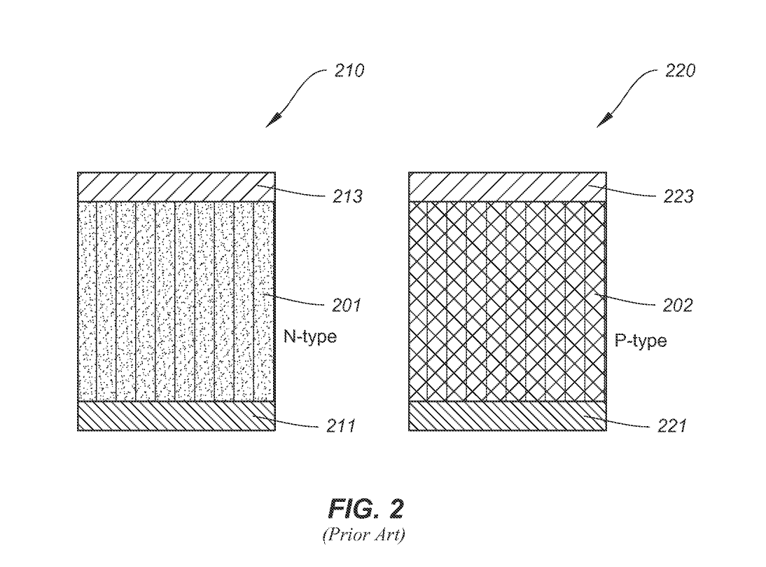

### 5. DETAILED DESCRIPTION OF THE INVENTION

The present invention is directed to thermoelectric devices. More particularly, the invention provides structures and methods for forming a multi-leg package (MLP) assembly. Merely by way of example, the invention has been applied to packaging a plurality of thermoelectric legs for the manufacture of a thermoelectric module. However, it would be recognized that the invention has a much broader range of applicability.

Since the thermoelectric power generation efficiency of a module in a temperature gradient is proportional to the temperature gradient, or the Carnot efficiency, the inability to take conventional thermoelectric materials to high temperatures often severely limits the power generation efficiency of thermoelectric products. As new thermoelectric products have been developed in recent years that can transform heat into electricity, improvements are needed in raising the power output of these products to deliver greater efficiency and lower cost. Most thermoelectric power generation products utilize some form of exhaust gas, such as from a car engine, to generate power, a two-dimensional temperature gradient is the relevant boundary condition with which to further improve thermoelectric modules. As such, structures and techniques are needed for thermoelectric modules so that these modules are able to withstand large temperature gradients, temperatures in excess of 300° C. on the hot side, and in excess of 100° C. on the cold side, according to certain embodiments.

In one embodiment, a thermoelectric leg includes a thermoelectric material. For example, an abundantly-supplied semiconductor material such as silicon is processed to form a plurality of nanostructure elements (e.g., one-dimensional wire structure, one-dimensional tube structure, two-dimensional layered structure, three-dimensional random voids and/or meshes structure) with a thermal conductivity between 0.1 W/m-K and 20 W/m-K while still provided as the bulk-sized structure for the thermoelectric material. In another example, the bulk-sized structure for the thermoelectric material includes a plurality of nanowires with high aspect ratio substantially aligned parallel along a length direction of the structure. In yet another example, the bulk-sized structure for the thermoelectric material includes a network of nanoholes, nanoparticles, and/or meshes without substantially aligned parallel along a length direction of the structure. In yet another example, the bulk-sized structure for the thermoelectric material includes a network of nanowires, nanoholes, nanoparticles, and/or meshes without a favored direction although the thermoelectric material is provided as an elongated column-like structure. In yet another example, the bulk-sized structure for the thermoelectric material includes a fill material occupying the intermediate regions between nanostructure elements (e.g., wire structure, or voids and/or meshes structure). In yet another example, the fill material is selected to bear a high thermal resistivity while keeping high electrical conductance only through the nanostructure elements (e.g., wire structure, or voids and/or meshes structure) and to also help strengthen the leg structure physically as a whole.

In another embodiment, certain structural modifications near both end regions of a TE leg are applied to at least partially relieve the thermal stress induced between the TE material and the end electrodes.

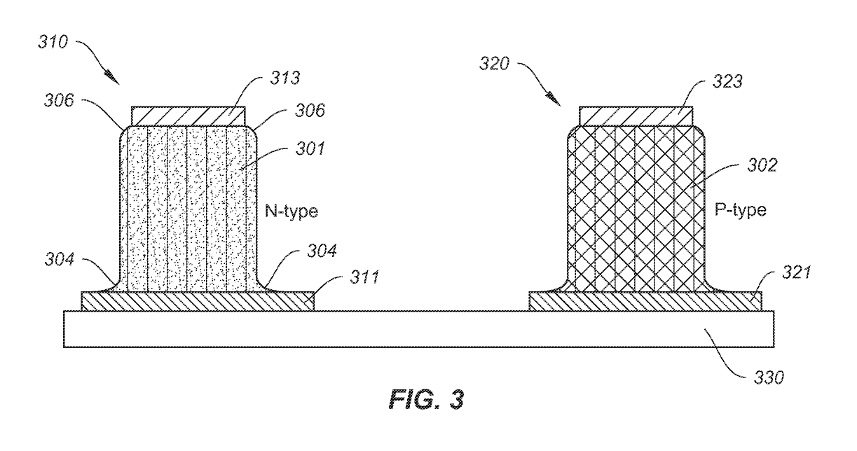

FIG. 3 is a simplified diagram showing bulk-sized thermoelectric legs according to certain embodiments. As shown, two TE legs 310 and 320 are respectively bonded onto a common conductor material 330 through their respectively electrodes to form a TE unicouple. For example, the TE leg 310 includes n-type thermoelectric material 301 with a first end region bonded with a first end electrode 311 and a second end region bonded with a second end electrode 313. The first end electrode 311 is attached to the conductor material 330. In another example, another TE leg 320 includes p-type thermoelectric material 302 with a first end region bonded with a first end electrode 321 and a second end region bonded with a second end electrode 323. The first end electrode 321 is attached to the conductor material 330.

In one embodiment, each of the TE legs 310 and 320 has a long length and a small cross section in order to increase thermal resistance for maintaining a temperature difference as large as possible across a thermal junction for achieving better thermoelectric power density. But such leg structure often imposes large thermal stress near the end regions of a TE leg as the TE leg is in contact with both the hot side and the cold side of a thermal junction.

In another embodiment, each of the TE legs 310 and 320 has the bulk-sized TE material that is made from a plurality of ultra-long nanowires aligned in the length direction. For example, each nanowire has a length of 400 μm or more with an aspect ratio of 1000 to 1. In another example, the plurality of ultra-long nanowires are formed into multiple arrays, each of which has an extended bulk-sized lateral dimension with interstitial regions filled with non-conductive fill material. In yet another example, the multiple arrays of nanowires can also be stacked in the length direction to achieve a prolonged length of the bulk-sized TE material.

Although the lateral dimension of a bulk-sized TE material (e.g., the thermoelectric material 301, the thermoelectric material 302) can become much larger than its length or height dimension, the bulk-sized TE material may contain internal structural elements that have a large length-to-width aspect ratio and thus are sensitive to the lateral stress imposed by thermal expansion after the conductor material (e.g., the conductor material 330) is contacted to the hot side of a thermal junction. One or more structural modifications can help relieve the stress and reduce contact breakdown or other device failure issues according to some embodiments.

According to one embodiment, the end regions of the bulk-sized TE material (e.g., the thermoelectric material 301, the thermoelectric material 302) are to have their edges and/or corners shaped in curved tail or rounded when each TE leg (e.g., the TE leg 310, the TE leg 320) is individually fabricated. For example, when fabricating each individual TE leg out of a large wafer-sized TE material through a serial of planar and/or cutting processes, the corner regions are intentionally left with a tail structure or cut to have a truncated shape. In another example, for the TE leg 310, one or more curved tail portions 304 are left around the first end region of the TE material 301 when the TE material 301 is cut from a larger-sized material and one or more truncated edges 306 are associated with the second end region of the TE material 301.

As shown in FIG. 3, the first end electrode 311 bonds to the entire area of the first end region that includes the one or more tail portions 304. For example, the end electrode 311 is subjected to contact with a hot-side region of a thermal junction, which may reach a temperature of 600° C. or more in many thermoelectric applications. In another example, the extended width provided by the one or more tail portions 304 improves structural flexibility of the first end region in both the lateral direction and in the length direction in order to adapt thermal expansion caused by the high temperature environment, thereby relieving the thermal stress imposed to the interface region and to the TE material.

Also as shown in FIG. 3, the first end electrode 313 bonds to the entire area of the second end region with the one or more truncated edges 306. For example, the end electrode 313 is subjected to contact with a cold-side region of the thermal junction, which is typically around the room temperature or a temperature below 100° C. In another example, when the end electrode 311 is subjected to contact with the hot-side region of the thermal junction at a high temperature, the deformation initiated at the first end region can affect the second end region through the thermoelectric material 301, causing lateral stress to the second end region relative to the cold-side contact material that is bonded to the second end region through the second end electrode 313. In yet another example, this stress is mainly imposed near the edges and/or corners of the second end region of the TE material 301; therefore, the one or more truncated edges 306 can effectively release the stress and ensure structural stability of the TE leg 310.

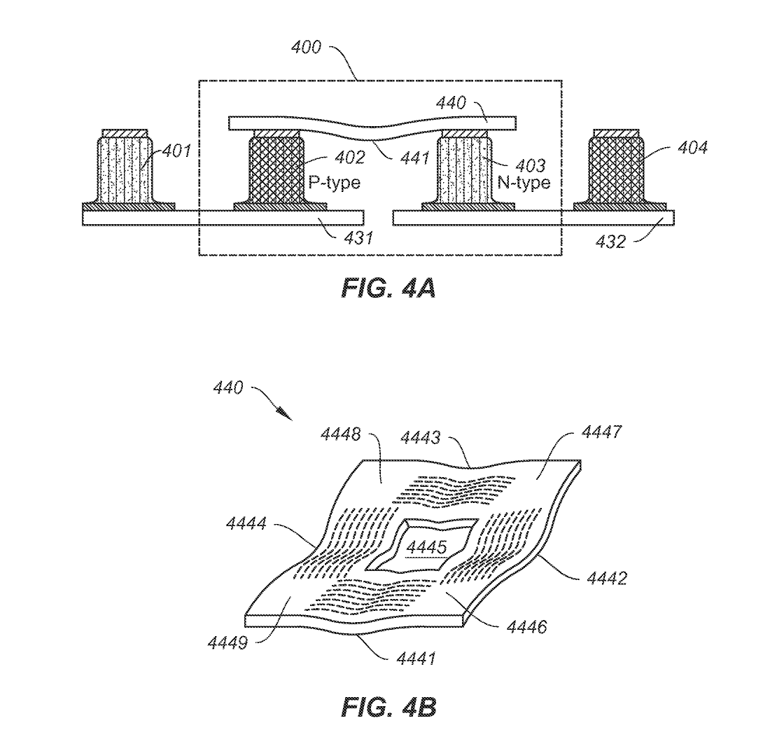

FIG. 4A is a simplified diagram showing a thermoelectric unicouple with a stress-relief conductive shunt material for assembly of a thermoelectric device according to one embodiment. As shown, the thermoelectric device is assembled by aligning a plurality of TE legs in serial-chain configuration alternatively with an n-type TE leg and a p-type TE leg, and the serial-chain configuration includes n-type TE legs 401 and 403 and p-type TE legs 402 and 404. For example, each of the n-type TE legs 401 and 403 is the same as the TE leg 310, and each of the p-type TE legs 402 and 404 is the same as the TE leg 320. In another example, the p-type TE leg 402 and the n-type TE leg 403 form a thermoelectric unicouple 400, which also includes a conductive shunt material 440. In yet another example, the conductive shunt material 440 is thermally and electrically conductive. In yet another example, the conductive shunt material 440 is coupled to one end of the p-type TE leg 402 and one end of the n-type TE leg 403. The other end of the p-type TE leg 402 is coupled to the neighboring n-type leg 401 through a conductor material 431 (e.g., a common conductor material 330), and the other end of the n-type TE leg 403 is coupled to the neighboring p-type leg 404 through a conductor material 432 (e.g., a common conductor material 330).

In one embodiment, the conductive shunt material 440 is configured to be a thin plate or sheet material with a region 441 near its middle region, and the region 441 can be bended under stress and serves as an intrinsic stress relief mechanism. For example, the conductive shunt material 440 is made by highly-conductive metal or alloy (e.g., copper and/or gold) and used to associate with a cold-side contact of a thermal junction applied by the thermoelectric device that includes the TE legs 401, 402, 403, and 404. In another example, the thermal expansion of the hot-side contact induces mechanical deformation or shift of the conductor material 431 and the conductor material 432 that are bonded to the bottom end electrodes (e.g., end electrodes 321 and 311) of the two TE legs 402 and 403, and such mechanical deformation or shift in turn pulls or pushes the top end electrodes (e.g., end electrodes 323 and 313) of the two TE legs 402 and 403. In yet another example, while the top end electrodes (e.g., end electrodes 323 and 313) of the two TE legs 402 and 403 are bonded to the conductive shunt material 440, the stress imposed to the top end electrodes of the two TE legs 402 and 403 can be properly relieved by bending the region 441 and/or stretching out the bended region 441 of the shunt material 440 without affecting the bonding between the conductive shunt material 440 and the top end electrodes of the two TE legs 402 and 403.

FIG. 4B is a simplified diagram showing the conductive shunt material 440 for forming an electric lead of a thermoelectric device according to one embodiment. As shown, the conductive shunt material 440 has an overall rectangular shape with a middle region that can be, under stress, bended in two perpendicular directions. For example, one of the two perpendicular directions is from an edge 4441 to an edge 4443, and the other of the two perpendicular directions is from an edge 4442 to an edge 4444. In another example, the conductive shunt material 440 has a central opening 4445 (e.g., in a rectangular shape or another shape). In yet another example, the illustration of the conductive shunt material 440 in FIG. 4B is not drawn to scale, and the dimensions and/or curvatures can be varied depending on shunt material selection and thermoelectric device packaging layout.

In one embodiment, flat regions 4446 and 4449 on the conductive shunt material 440 are used for respectively bonding with two TE legs to form a thermoelectric unicouple (e.g., a thermoelectric unicouple 400), and flat regions 4447 and 4448 on the conductive shunt material 440 are used for respectively bonding with another two TE legs to form another thermoelectric unicouple (e.g., another thermoelectric unicouple 400). For example, these two thermoelectric unicouples are connected in an electrical parallel configuration. In another example, one of these two thermoelectric unicouples serves as a backup for the other thermoelectric unicouple, so that if one or two TE legs for one of the two thermoelectric unicouples fail, the electrical connection for the serial-chain configuration of the whole thermoelectric device can still work by passing the current through the backup unicouple.

In another embodiment, not only the two thermoelectric unicouples under a single piece of conductive shunt material 440 can be formed in a two-dimensional configuration, but also the serial-chain configuration of thermoelectric unicouples can be arranged in a two-dimensional package. For example, the thermal stress associated with the whole packaged thermoelectric device that includes all unicouples is also two dimensional. In another example, under stress, the middle region of the conductive shunt material 440 can be bended in each of the two directions, the first direction extending from the edge 4441 to the edge 4443 and the second direction extending from the edge 4442 to the edge 4444. In yet another example, the conductive shunt material 440 as shown in FIG. 4B is configured to relieve thermal stress imposed along the first direction and/or the second direction. Particularly, the bending portion along the first direction provides structural flexibility to respond a pulling and/or bending force along the second direction, and the bending portion along the second direction provides structural flexibility to respond a pulling and/or bending force along the first direction.

In yet another example, the central opening 4445 also provides stress relief by taking away material from the most twisted central portion of the conductive shunt material 440. For example, the two-dimensional rectangular-shaped conductive shunt material 440 is modified to be a sheet or thin plate adaptive to the stress imposed from either one or both of two lateral directions (e.g., the first direction and/or the second direction) by allowing one-dimensional stretching and/or bending of the flexible curved regions 4441 and 4443 in only one direction and/or by allowing one-dimensional stretching and/or bending of the flexible curved regions 4442 and 4442 in only another direction.

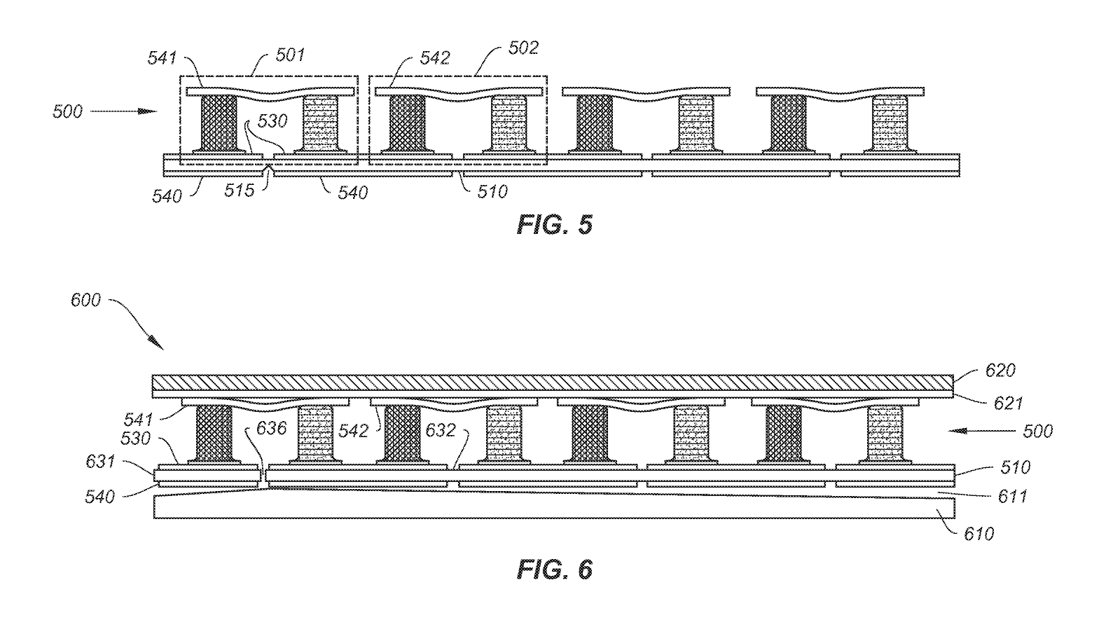

FIG. 5 is a simplified diagram showing a series of thermoelectric unicouples on a base structure for fabrication of a thermoelectric device according to one embodiment of the present invention. This diagram is merely an example, which should not unduly limit the scope of the claims. One of ordinary skill in the art would recognize many variations, alternatives, and modifications. As shown in FIG. 5, a series 500 of thermoelectric unicouples includes thermoelectric unicouples 501 and 502, and is placed with alignment onto a base structure 510. For example, the thermoelectric unicouple 501 is a thermoelectric unicouple 400, and the thermoelectric unicouple 502 is another thermoelectric unicouple 400. In another example, the thermoelectric unicouple 501 includes a conductive shunt material 541 (e.g., a conductive shunt material 440) bonded to top ends of two TE legs, and the thermoelectric unicouple 502 includes a conductive shunt material 542 (e.g., another conductive shunt material 440) bonded to top ends of two other TE legs. In yet another example, each of the conductive shunt materials 541 and 542 is thermally and electrically conductive.

In one embodiment, the base structure 510 is electrically insulating but thermally highly conductive. For example, the base structure 510 includes a plate made of a ceramic material. In another example, the ceramic material is silicon nitride (Si₃N₄). In another embodiment, a front-side surface of the base structure 510 is attached to a plurality of metal contact pads 530 (e.g., a plurality of conductor materials 431) for bonding TE legs belonging to different thermoelectric unicouples. For example, each of the plurality of metal contact pads 530 is thermally and electrically conductive. In another example, the base structure 510 is attached to one metal contact pad 530 (e.g., a conductor material 431) in order to bond the two TE legs belonging to the neighboring thermoelectric unicouples 501 and 502. In yet another example, referring to FIG. 4B, as a redundant chain of TE legs is associated to each serial chain of TE legs for packaging the thermoelectric device, each contact pad 530 is provided with a rectangular shape that is configured to bond two additional TE legs belonging to two other thermoelectric unicouples in the redundant chain. In another embodiment, a backside surface of the base structure 510 is attached to a plurality of metal contact pads 540. For example, each of the plurality of metal contact pads 540 is thermally and electrically conductive. In another example, a metal contact pad 540 is the same as a metal contact pad 530. In yet another example, the plurality of metal contact pads 540 is aligned with the plurality of metal contact pads 530.

In order to assemble a large thermoelectric device, a plurality of TE legs are included in each serial-chain configuration, and a plurality of such serial-chain configurations are aligned to form a two-dimensional array of TE legs over a large area of the base structure 510 according to certain embodiments. For example, the base structure 510 is a rectangular-shaped plate attached to N×M metal contact pads 530 and N×M metal contact pads 540, wherein N and M are integers greater than 1. In another example, each metal contact pad 530 is aligned to bond with four TE legs.

As shown in FIG. 5, the base structure 510 includes one or more line notches 515, each of which is scribed from the backside surface between two metal contact pads 540. In one embodiment, the one or more line notches 515 are arranged so that each line notch 515 is separated from a neighboring line notch 515 by a few metal contact pads 540. For example, the base structure 510 is attached to 20×12 metal contact pads 530 and 20×12 metal contact pads 540, and a line notch 515 is includes for every four metal contact pads 540. In another example, a denser or looser arrangement of line notches 515 can be applied, so can the number N and M be varied a lot depending on specific applications. In another embodiment, the base structure 510 with the one or more line notches 515 is configured to form a hot-side thermal contact of the assembled thermoelectric device. For example, the one or more line notches 515 serve a stress-relief mechanism for the thermoelectric device, especially for the contact region on the hot side of a thermal junction.

FIG. 6 is a simplified diagram showing a thermoelectric device including the series 500 of thermoelectric unicouples on the base structure 510 according to one embodiment of the present invention. This diagram is merely an example, which should not unduly limit the scope of the claims. One of ordinary skill in the art would recognize many variations, alternatives, and modifications. As shown in FIG. 6, the thermoelectric device 600 includes the series 500 of thermoelectric unicouples, the base structure 510, the plurality of metal contact pads 540, a hot-side plate 610, a hot-side thermal interface material 611, a cold-side plate 620, and a cold-side thermal interface material 621.

In one embodiment, a volume of space between the hot-side plate 610 and the cold-side plate 620 is used to form a thermal junction. For example, the base structure 510 is in thermal contact with the hot-side plate 610 of the thermal junction through the plurality of metal contact pads 540 and/or the hot-side thermal interface material 611. In another example, the conductive shunt materials (e.g., the conductive shunt materials 541 and 542) are in thermal contact with the cold-side plate 620 of the thermal junction through the cold-side thermal interface material 621. In another example, the hot-side plate 610 is associated with a heat source at a high temperature (e.g., a waste-heat source with exhaust gas at 600° C. or higher), and the cold-side plate 620 is associated with a cooling source (e.g., ambient air or water at a temperature substantially less than 100° C.).

In another embodiment, when the base structure 510 is just attached to the hot-side plate 610 through the plurality of metal contact pads 540 and/or the hot-side thermal interface material 611, a large temperature difference (e.g., 600° C. or more) between the hot-side plate 610 and the just-attached base structure 510 causes mechanical deformation to the hot-side plate 610. For example, part of the hot-side plate 610 protrudes up, and part of the hot-side plate 610 bends down. In another example, such mechanical deformation further transfers the stress to push up and/or drag down the corresponding portions of the base structure 510, thereby imposing stress to the TE legs that are bonded onto the base structure 510 through the plurality of metal contact pads 530.

In yet another embodiment, under such thermal stress (e.g., the thermal stress mainly perpendicular to the backside surface of the base structure 510), the one or more line notches 515 become the weakest regions of the base structure 510. For example, a desirable manner of stress relief is to break the base structure 510 into multiple blocks along the one or more line notches 515. In another example, the multiple blocks includes a block 631 and a block 632 separated by a gap 636. In yet another example, after breaking into multiple blocks along the one or more line notches 515, each block on its backside surface still bonds to the hot-side plate 610 through one or more metal contact pads 540 and/or the hot-side thermal interface material 611, and on its front-side surface still bonds to one or more TE legs through one or more metal contact pads 530, even though the blocks may be tilted somewhat from their original positions before the breaking occurs. In yet another example, after breaking into multiple blocks along the one or more line notches 515, the stress level around the TE legs and their bonding regions with the one or more metal contact pads 530 is substantially lowered.

According to one embodiment, without any line notch 515, the thermal stress imposed onto the base structure 510 may cause bending of the base structure and further pass the thermal stress to the TE legs that are bonded to the one or more metal contact pads 530, making those TE legs, especially their bonding regions, the weakest region to break or fail. For example, with the one or more line notches 515, the base structure 510 allows the use of a large initially non-breaking area for assembling a plurality of TE legs in multiple serial-chain configurations arranged in a two-dimensional device package. In another example, breaking along the one or more line notches 515 can provides benefit to the stress relief of the whole thermoelectric device but not affect the nominal electrical and/or thermal conductions through the plurality of TE legs. In yet another example, the thermoelectric device 600 can simplify packaging technique for TE legs (e.g., silicon nanowire-based TE legs) that have high thermoelectric performance by themselves, but are relative weak in mechanical strength to handle large thermal stress. In yet another example, the thermoelectric device 600 can make the assembled thermoelectric device highly adaptive to extreme conditions under which conventional devices often are unable to generate thermoelectric power efficiently.

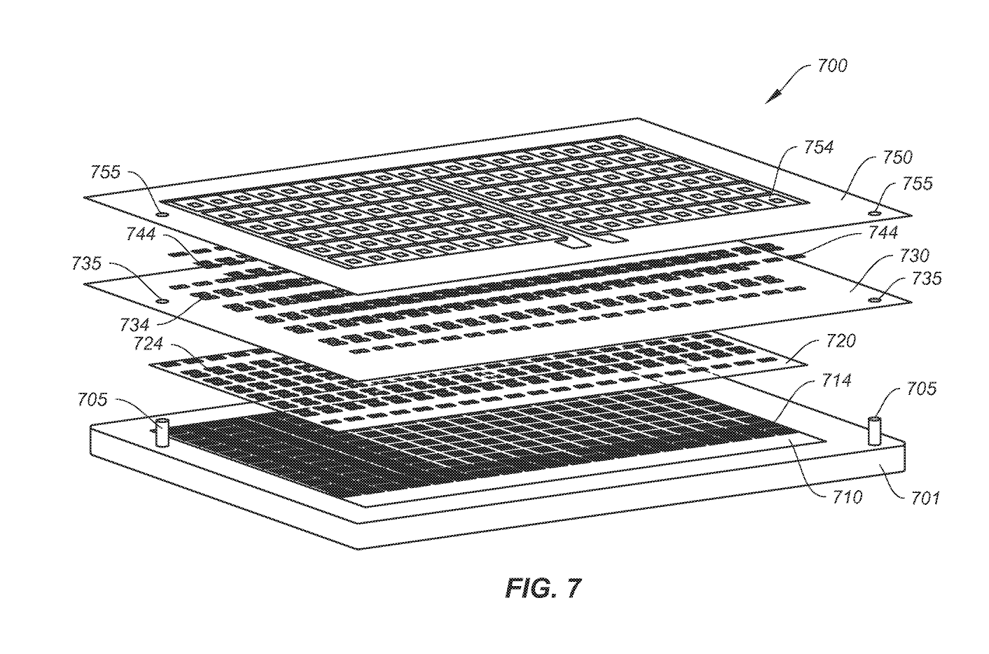

FIG. 7 is a simplified diagram showing a method for assembling a multi-leg package (MLP) as a thermoelectric device including the series 500 of thermoelectric unicouples on the base structure 510 according to one embodiment of the present invention. This diagram is merely an example, which should not unduly limit the scope of the claims. One of ordinary skill in the art would recognize many variations, alternatives, and modifications.

As shown in FIG. 7, a multi-leg package (MLP) thermoelectric module 700 is formed through a multi-step assembly process. First, a base plate 701 is provided with one or more built-in alignment markers 705 (e.g., one or more alignment pins). For example, the base plate 701 is made of thermally conductive material and used as a hot-side plate (e.g., the hot-side plate 610) in thermoelectric applications. In another example, the base plate 701 has a length dimension and a width dimension that are chosen to provide packaging of multiple arrays (e.g., twenty arrays) of thermoelectric legs into the thermoelectric module 700. In yet another example, each array of TE legs includes multiple rows, each of which contains multiple units. Each of these units includes four TE legs as shown in FIGS. 4A and 4B.

Second, a bottom contact sheet 710 is placed on the base plate 701. In one embodiment, the contact sheet 710 (e.g., the base structure 510) supports a plurality of contact regions 714 (e.g., the plurality of metal contact pads 530). For example, each contact region 714 (e.g., each metal contact pad 530) serves as a bottom contact for a group of four TE legs. In another embodiment, the contact sheet 710 (e.g., the base structure 510) is made substantially of a ceramic material in order to withstanding a high temperature. For example, the ceramic material has a thermal expansion coefficient similar to that of silicon-based thermoelectric legs. In another example, silicon nitride is used as the ceramic material.

As shown in FIG. 7, the plurality of contact regions 714 (e.g., the plurality of metal contact pads 530) are arranged in an ordered array. In one embodiment, each contact region 714 contains a highly conductive material. For example, each contact region 714 is a layer of copper alloy material directly bonded onto the front-side surface of the contact sheet 710 (e.g., the base structure 510). In another embodiment, to keep the contact sheet 710 (e.g., the base structure 510) flat under thermal stress, another plurality of contact regions (e.g., the plurality of metal contact pads 540) is bonded over the same region on opposite side of the contact sheet 710 (e.g., the base structure 510). For example, each of the another plurality of contact regions is also a layer of copper alloy material directly bonded onto the backside surface of the contact sheet 710 (e.g., the base structure 510). In another example, the contact sheet 710 (e.g., the base structure 510) is in the thermal contact with the base plate 701 (e.g., the hot-side plate 610) through the another plurality of contact regions (e.g., the plurality of metal contact pads 540) and/or a hot-side thermal interface material (e.g., the hot-side thermal interface material 611). In another embodiment, the contact sheet 710 (e.g., the base structure 510) includes pre-scribed multiple line notches (e.g., multiple line notches 515) on the backside surface. For example, each line notch is separated from a neighboring line notch by a few metal contact pads (e.g., four metal contact pads 540) to provide a stress relief mechanism without adversely affecting module functionality.

Third, over the plurality of contact regions 714 (e.g., the plurality of metal contact pads 530), a coupling material 724 is applied. In one embodiment, over each contact region 714, the coupling material 724 is placed over four local regions. For example, the four local regions are located near four corners of a square-shaped contact region 714 respectively. In another example, each local region is configured to couple with a TE leg. In yet another example, among the four TE legs to be bonded to the four local regions, one p-type leg and one n-type leg form a thermoelectric unicouple, and the other p-type leg and the other n-type leg form a redundant unicouple as shown in FIGS. 4A and 4B. In yet another example, the coupling material 724 is a brazing alloy that can support operation of thermoelectric module at a high temperature (e.g., 600° C. or higher) without any bonding failure. In another embodiment, an alignment screen 720 with properly positioned openings is used to allow the coupling material 724 to be printed as a layer overlying the right regions on the corresponding contact regions 714 (e.g., the plurality of metal contact pads 530). For example, the alignment is performed by associating one or more holes in the alignment screen 720 with the one or more built-in alignment markers 705 of the base plate 701 respectively.

Fourth, an alignment sheet 730 is placed on top of the contact sheet 710 (e.g., through the coupling material 724). For example, the alignment is performed using one or more feature holes 735 on the alignment sheet 730 to mate with the one or more built-in alignment markers 705 of the base plate 701 respectively. In another example, the alignment sheet 730 includes multiple patterned openings 734, four in each group aligned to the corresponding four local regions (e.g., the corresponding four local regions located near four corners of a square-shaped contact region 714 respectively). In yet another example, after the placement of the alignment sheet 730, the coupling material 724 on each local region of a contact region 714 fills the corresponding patterned opening 734, ready for bonding with an individual TE leg.

Fifth, a plurality of TE legs 744 are placed onto the plurality of contact regions 714 (e.g., the plurality of metal contact pads 530) through the coupling material 724 in order to form an array of TE legs. In one embodiment, the array of the TE legs 744 includes multiple rows and columns arranged in a predetermined order that has been determined based on desired thermoelectric functionalities and electrical serial and/or parallel connections for the array. In another embodiment, each TE leg 744 (e.g., a p-type TE leg or an n-type TE leg) is aligned to engage with the coupling material 724 through a corresponding patterned opening 734. For example, a group of four TE legs are bonded to the same contact region 714 (e.g., the same metal contact pad 530) with the coupling material 724, through four patterned openings 734 aligned to the corresponding four local regions of the same contact region 714 (e.g., the corresponding four local regions located near four corners of a square-shaped contact region 714 respectively). In another example, the alignment sheet 730 is configured to facilitate placement of individual TE leg 744, each with relative small dimensions in millimeter ranges, to desired positions in order to bond with the contact region 714.

Sixth, a plurality of shunt plates 754 (e.g., a plurality of conductive shunt materials that include the conductive shunt materials 541 and 542) are placed to selectively bond with top ends of the plurality of TE legs 744. In one embodiment, each shunt plate 754 (e.g., the conductive shunt material 541 or 542) is configured to bond with four TE legs 744, two of which (e.g., on the left) come from one group of four TE legs 744 that are bonded onto one contact region 714 and the other two of which (e.g., on the right) come from another group of four TE legs 744 that are bonded onto another contact region 714. For example, the bonding of the shunt plate 754 over the four TE legs 744 forms a redundant thermoelectric unicouple for each of the two contact regions 714. In another example, the shunt plate 754 serves as an electrical current connector between the unicouples. In another embodiment, to facilitate positioning of the plurality of shunt plates 754 over the plurality of TE legs 744 previously arranged into an array, the plurality of shunt plates 754 are prefabricated into a shunt sheet 750 (e.g., a metal lead frame) by patterning. For example, the shunt sheet 750 also includes one or more alignment features 755 to be aligned with the one or more alignment markers 705 respectively when the shunt sheet 750 is placed onto the plurality of TE legs 744. In another example, the prefabrication of the plurality of shunt plates 754 within the shunt sheet 750 is performed to provide desired electrical connections from one shunt plate 754 to another shunt plate 754 that include external electrical leads for the assembled thermoelectric module 700. In yet another embodiment, the plurality of shunt plates 754 (e.g., the plurality of conductive shunt materials that include the conductive shunt materials 541 and 542) are in thermal contact with a cold-side plate (e.g., the cold-side plate 620) through a cold-side thermal interface material (e.g., the cold-side thermal interface material 621). For example, the cold-side plate (e.g., the cold-side plate 620) is placed on the plurality of shunt plates 754 (e.g., the plurality of conductive shunt materials that include the conductive shunt materials 541 and 542) through the cold-side thermal interface material (e.g., the cold-side thermal interface material 621).

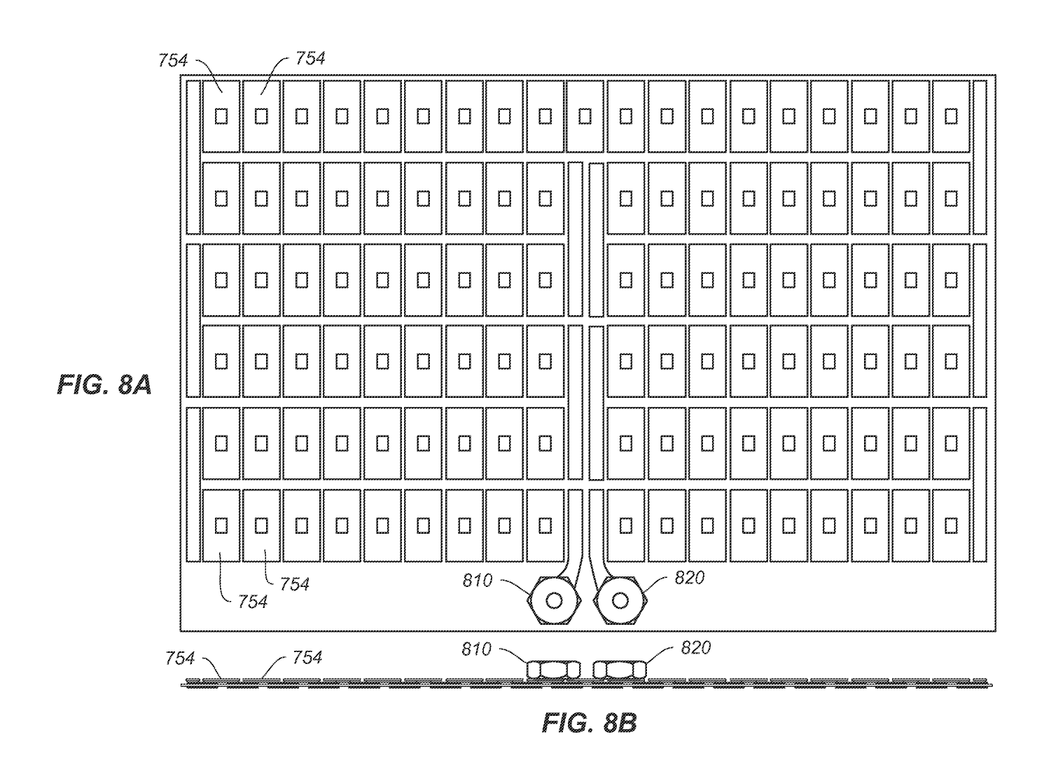

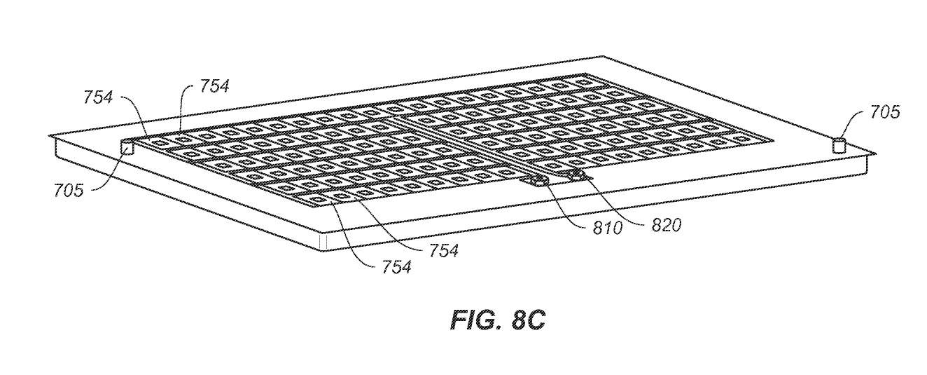

FIGS. 8A-8C are simplified diagrams showing views of certain components of the multi-leg package (MLP) 700 assembled as shown in FIG. 7 according to certain embodiments of the present invention. These diagrams are merely examples, which should not unduly limit the scope of the claims. One of ordinary skill in the art would recognize many variations, alternatives, and modifications. For example, FIG. 8A shows a top view, and FIG. 8B shows a side view.

As shown in FIGS. 8A-8C, the plurality of shunt plates 754 (e.g., the plurality of conductive shunt materials that include the conductive shunt materials 541 and 542) are coupled to the plurality of TE legs 744. In one embodiment, other mechanical connections that may have existed initially are trimmed to avoid undesirable shorting from one shunt plate to another shunt plate. In another embodiment, two electrical leads 810 and 820 represent a main input terminal and a main output terminal respectively. For example, the main input terminal 810 and the main output terminal 820 are connected to external lines using the threaded nuts attached thereon. In yet another embodiment, the plurality of shunt plates 754 are patterned according to a predetermined arrangement of the plurality of TE legs 744 placed in multiple rows and columns. For example, the plurality of shunt plates 754 are arranged in rows and columns to form a specific electrical conduction path along an entire row before connecting to a second row. In another example, the plurality of shunt plates 754 are arranged to form an electrical conduction path from a middle common lead to one side along one row in one direction followed by another path along a next row in an opposite direction.

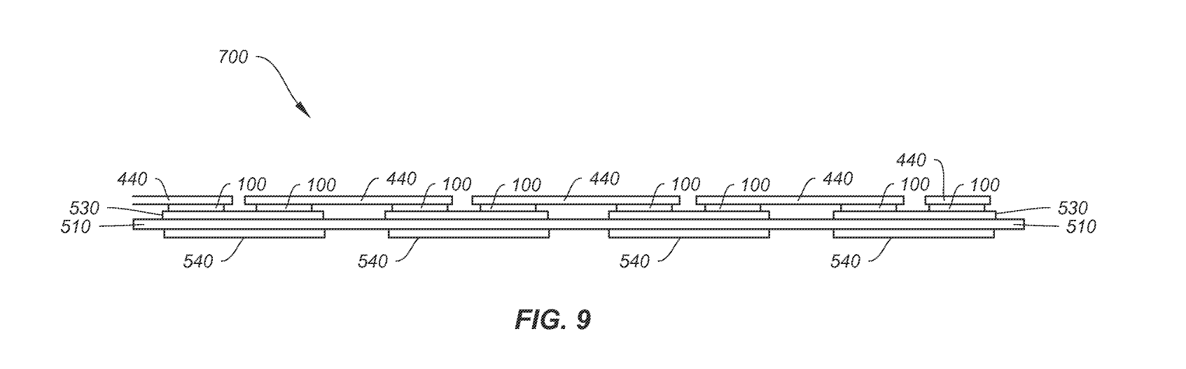

FIG. 9 is a simplified diagram showing certain components of the multi-leg package (MLP) 700 as shown in FIG. 6, FIG. 7, and/or FIG. 8 according to certain embodiments of the present invention. This diagram is merely an example, which should not unduly limit the scope of the claims. One of ordinary skill in the art would recognize many variations, alternatives, and modifications.

As shown in FIG. 9, the multi-leg package (MLP) 700 includes a base substrate 510 (e.g., the contact sheet 710), attached to an array of metal contact pads 530 (e.g., an array of contact regions 714) on the front-side surface and another array of metal contact pads 540 on the backside surface substantially in a mirror symmetry. In one embodiment, the base substrate 510 is made of a material that is an electrical insulator but a good thermal conductor. For example, the base substrate 510 is made of a ceramic material. In another embodiment, the metal contact pads 530 and the metal contact pads 540 are made of a material that is both thermally and electrically conductive. For example, the metal contact pads 530 and the metal contact pads 540 are made of copper. In another example, the metal contact pads 530 are arranged in multiple rows and columns and separated by a spacing from each other. In yet another example, the metal contact pads 540 are arranged in multiple rows and columns and separated by a spacing from each other.

Also as shown in FIG. 9, the multi-leg package (MLP) 700 further includes a plurality of TE legs 100 (e.g., the plurality of TE legs 744) that are aligned with the metal contact pads 530 on the base substrate 510 respectively. In one embodiment, the plurality of TE legs 100 are arranged in a predetermined pattern of rows and columns so that each leg is separated from another and each metal contact pad 530 is aligned to support at least two TE legs 100. For example, these two TE legs 100 include an N-type TE leg 210 and a P-type TE leg 220. In another example, in each row, the TE legs 100 are arranged in a series with an N-type and P type alternating order. In another embodiment, each row of TE legs 100 is grouped with a redundant row of TE legs 100 that has exactly the same N-type and P-type alternating order. For example, two redundant pairs of N-type and P-type TE legs 100 have parallel electrical paths. In another example, the next two rows of TE legs 100, one being redundant to the other, have an N-type and P-type alternating order that is shifted one leg position compared to the first two rows.

Further as shown in FIG. 9, the multi-leg package (MLP) 700 also includes a plurality of shunt plates 440 (e.g., a plurality of shunt plates 754) on the plurality of TE legs 100 (e.g., the plurality of TE legs 744). In one embodiment, the plurality of shunt plates 440 (e.g., the plurality of shunt plates 754) are prefabricated into a metal lead frame (e.g., a shunt sheet 750). For example, the metal lead frame includes multiple shunt plates 440 mechanically tabbing together by one or more metal components (e.g., one or more copper components). In another example, the metal lead frame is aligned with the plurality of TE legs 100 (e.g., the plurality of TE legs 744) in their predetermined positions on individual metal contact pads 530, so that each shunt plate 440 is in position to form an electrical coupling with four TE legs 100 from two successive rows and two successive columns. In yet another example, after the metal lead frame is placed onto the plurality of TE legs 100 (e.g., the plurality of TE legs 744), mechanical connections that have existed initially are trimmed to avoid undesirable shorting from one shunt plate 440 to another shunt plate 440. In yet another example, after the trimming, the individual shunt plates 440 each appear as a standalone piece as their mechanical contacts are only with the attachment to the corresponding TE legs 100.

In another embodiment, each TE leg 100 has its first end placed on a metal contact pad 530 and has its second end attached to a shunt plate 440 (e.g., a sheet conductor). For example, the plurality of shunt plates 440 (e.g., the plurality of shunt plates 754) complete an electrical path throughout all of the plurality of TE legs 100 (e.g., the plurality of TE legs 744) until reaching the end terminals (e.g., the electrical leads 810 and 820). In another example, along any row direction, the electrical path is a daisy-chain connection by going from a first shunt plate 440 down to a first TE leg 100, through a metal contact pad 530 that supports the first TE leg 100, to a second TE leg that of a different type from the first TE leg 100, and then up to a second shunt plate 440 that is next to the first shunt plate 440 but have no direct mechanical connection after the mechanical connections that have existed initially in the metal lead frame are trimmed to avoid undesirable shorting from one shunt plate 440 to another shunt plate 440.

As discussed above and further emphasized here, FIGS. 6-9 are merely examples, which should not unduly limit the scope of the claims. One of ordinary skill in the art would recognize many variations, alternatives, and modifications. For example, the rows and columns of the TE legs 100 are switched. In another example, the redundancy configuration of the TE legs 100 is varied. In yet another example, the TE legs near an edge of the multi-leg package (MLP) 700 and/or near an end of each row are attached with only half-sized shunt plate 440 (e.g., half-sized sheet conductor). In yet another example, the base substrate 510 (e.g., the contact sheet 710) is made of a polyimide material.

In yet another example, the plurality of TE legs 744 are bonded with the plurality of contact regions 714 (e.g., the plurality of metal contact pads 530) through one or more diffusion barrier materials, one or more thermionic barrier materials, and/or one or more bonding materials (e.g., one or more soldering bonding materials, one or more brazing bonding materials). In yet another example, the plurality of TE legs 744 are bonded with the plurality of shunt plates 754 (e.g., a plurality of conductive shunt materials that include the conductive shunt materials 541 and 542) through one or more diffusion barrier materials, one or more thermionic barrier materials, and/or one or more bonding materials (e.g., one or more soldering bonding materials, one or more brazing bonding materials).

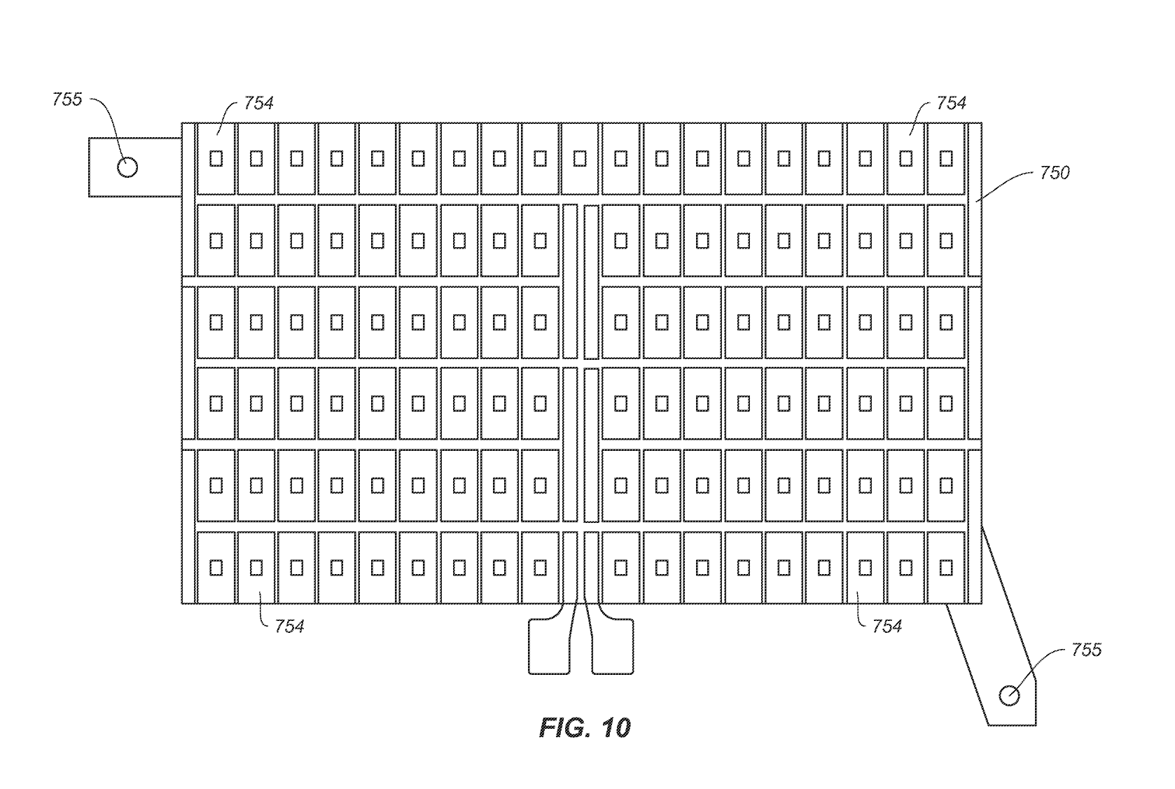

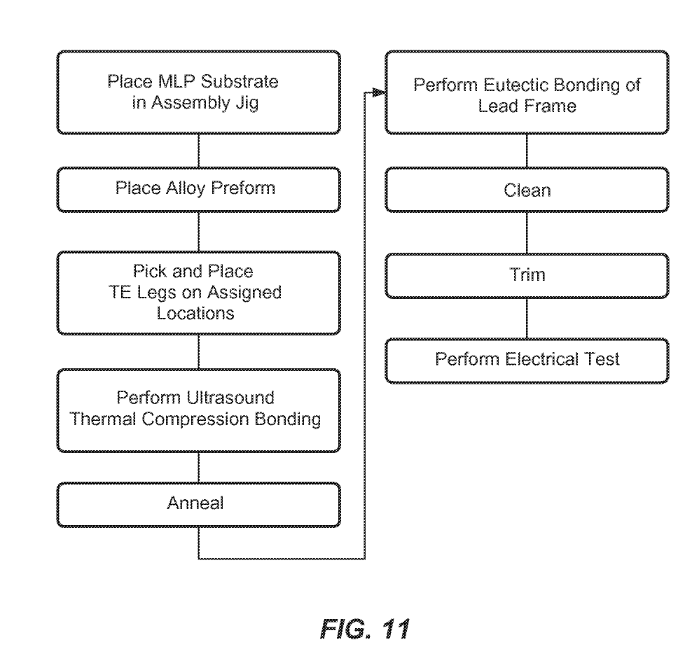

In yet another example, the metal lead frame (e.g., the shunt sheet 750) is replaced by a tape-backed lead frame. In yet another example, the metal lead frame (e.g., the shunt sheet 750) is replaced by a polyimide lead frame, as shown in FIG. 10.

FIG. 10 is a simplified diagram showing a polyimide lead frame as part of the multi-leg package (MLP) 700 as shown in FIG. 6, FIG. 7, FIG. 8, and/or FIG. 9 according to one embodiment of the present invention. This diagram is merely an example, which should not unduly limit the scope of the claims. One of ordinary skill in the art would recognize many variations, alternatives, and modifications. As shown in FIG. 10, the polyimide lead frame (e.g., the shunt sheet 750) is made from a standalone polyimide film with embedded metal foil (e.g., copper foil) in predetermined circuit patterns.

FIG. 11 is a simplified diagram showing a method of making certain components of the multi-leg package (MLP) 700 as shown in FIG. 6, FIG. 7, FIGS. 8A-8C, and/or FIG. 9 according to one embodiment of the present invention. This diagram is merely an example, which should not unduly limit the scope of the claims. One of ordinary skill in the art would recognize many variations, alternatives, and modifications.

As shown in FIG. 11, the method includes the following processes:
(a) placing a multi-leg package (MLP) substrate in an assembly jig. For example, the multi-leg package (MLP) substrate (e.g., the bottom contact sheet 710) is placed in the assembly jig (e.g., onto the base plate 701). In another example, the multi-leg package (MLP) substrate includes a ceramic plate (e.g., a silicon nitride ceramic plate) that is capped by copper pads (e.g., the plurality of metal contact pads 530 and 540) on two sides in mirror symmetry.
(b) placing alloy pre-form (e.g., a preformed alloy foil) in each leg position. For example, the preformed alloy foil includes the coupling material 724 (e.g., a brazing alloy).
(c) picking each TE leg and placing the TE leg in an assigned locations. For example, the picking and placing of each TE leg is performed by a bonder. In another example, the TE leg is a TE leg 744 (e.g., an N-type TE leg or a P-type TE leg). In yet another example, the TE legs are placed in multiple rows and columns on pre-assigned locations where the brazing alloy layer has been printed.
(d) using an ultrasound and/or compression process to achieve metallurgical bonding. In one embodiment, the TE legs (e.g., the TE legs 744) in multiple rows and columns are temporarily fixed at their locations by the paste-form bonding material during the pick and place process. For example, a precise weight object is placed onto the TE legs (e.g., the TE legs 744) to hold the TE legs in their positions. In another example, the weight object is properly aligned by placing its one or more alignment holes onto one or more alignment pins (e.g., the one or more alignment markers 705) respectively on the assembly jig. In another embodiment, with the weight object, the existing structure for the multi-leg package (MLP) 700 is loaded into a vacuum environment for performing a ultrasound and/or compression process. For example, the ultrasound and/or compression process is preformed at a high temperature under certain high-temperature and high-vacuum conditions. In another example, the brazing alloy melts before the TE leg 744 and the plurality of contact regions 714 (e.g., the plurality of metal contact pads 530) and subsequently forms a strong bond between the TE leg 744 and the contact regions 714.
(e) performing an anneal to reduce void formation in the metallurgical bond.
(f) performing eutectic bonding to attach a metal lead frame to the TE legs that are already on the multi-leg package. In one embodiment, the metal lead frame includes the plurality of shunt plates 754 that are prefabricated into a shunt sheet 750 by patterning. In another embodiment, the metal lead frame (e.g., the shunt sheet 750) includes a plurality of shunt plates (e.g., the plurality of shunt plates 754) that are fabricated from a whole piece of sheet conductor so that each shunt plate has at least some small tabs retained to link with its neighboring shunt plates to avoid falling apart.
(g) performing cleaning. For example, the cleaning process is performed by using hot deionized (DI) water.
(h) trimming the metal lead frame. In one embodiment, after the metal lead frame is firmly attached to the top ends of the brazed TE legs, the tabs that link a shunt plate to its neighboring shunt plates are trimmed (e.g., by laser) to clean up the separation between neighboring shunt plates and thus ensure the only electrical path between the neighboring shunt plates is to go through corresponding TE legs attached underneath. In another embodiment, after the trimming, individual shunt plates 440 each appear as a standalone piece as their mechanical contacts are only with the attachment to the corresponding TE legs 100.
(i) performing an electrical test. For example, the electrical test includes open-circuit test.

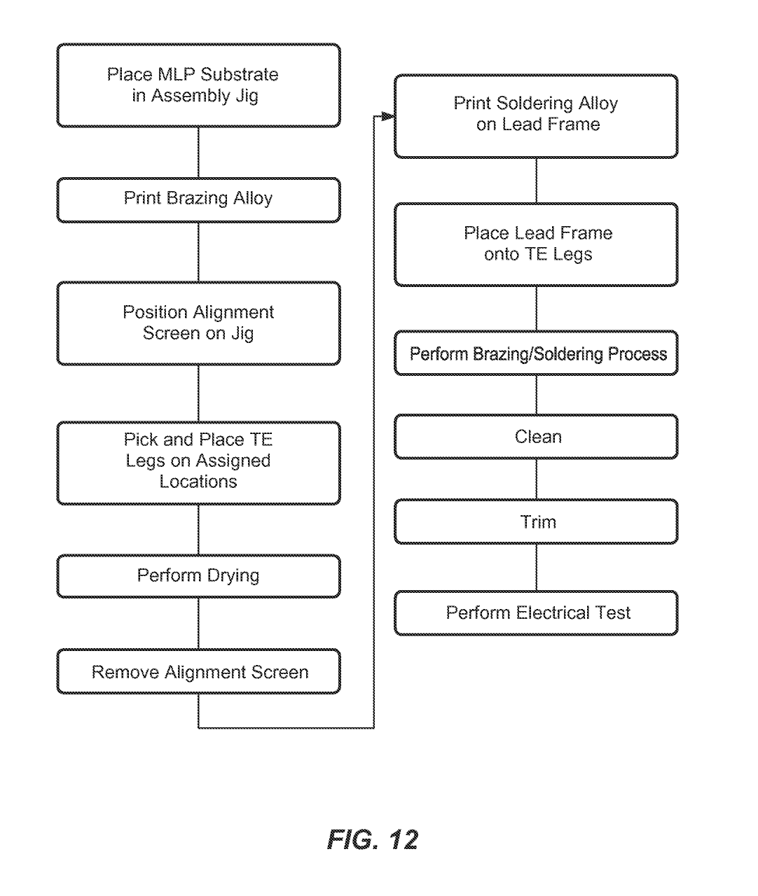

FIG. 12 is a simplified diagram showing a method of making certain components of the multi-leg package (MLP) 700 as shown in FIG. 6, FIG. 7, FIGS. 8A-8C, and/or FIG. 9 according to another embodiment of the present invention. This diagram is merely an example, which should not unduly limit the scope of the claims. One of ordinary skill in the art would recognize many variations, alternatives, and modifications.

As shown in FIG. 12, the method includes the following processes:
(a) placing a multi-leg package (MLP) substrate in an assembly jig. For example, the multi-leg package (MLP) substrate (e.g., the bottom contact sheet 710) is placed in the assembly jig (e.g., onto the base plate 701). In another example, the multi-leg package (MLP) substrate includes a ceramic plate (e.g., a silicon nitride ceramic plate) that is capped by copper pads (e.g., the plurality of metal contact pads 530 and 540) on two sides in mirror symmetry. In yet another example, the copper pads (e.g., the plurality of metal contact pads 530) are arranged in predetermined rows and columns, and other copper pads (e.g., the plurality of metal contact pads 540) are also arranged in corresponding predetermined rows and columns.
(b) placing a preformed alloy foil in each leg position. For example, the preformed alloy foil includes the coupling material 724 (e.g., a brazing alloy). In another example, the placement of the preformed alloy foils is performed by using the alignment screen 720.
(c) placing an alignment screen (e.g., the alignment sheet 730) to align with the assembly jig (e.g., to align with the base plate 701). For example, the alignment screen (e.g., the alignment sheet 730) is used to guide the to-be-placed TE legs (e.g., the plurality of TE legs 744).
(d) picking each TE leg and placing the TE leg in an assigned locations. For example, the picking and placing of each TE leg is performed by a bonder. In another example, the TE leg is a TE leg 744 (e.g., an N-type TE leg or a P-type TE leg). In yet another example, the TE legs are placed in multiple rows and columns on pre-assigned locations where the brazing alloy layer has been printed.
(e) performing a drying process. In one embodiment, the TE legs (e.g., the TE legs 744) in multiple rows and columns are temporarily fixed at their locations by the paste-form bonding material during the pick and place process. For example, a precise weight object is placed onto the TE legs (e.g., the TE legs 744) to hold the TE legs in their positions. In another example, the weight object is properly aligned by placing its one or more alignment holes onto one or more alignment pins (e.g., the one or more alignment markers 705) respectively on the assembly jig. In another embodiment, with the weigh member, a drying process is performed to remove moisture around the TE legs and the alloy layer (e.g., the brazing alloy).
(f) removing the alignment screen (e.g., the alignment sheet 730).
(g) placing a soldering alloy layer onto a metal lead frame.
(h) placing the metal lead frame onto top ends of the TE legs (e.g., the TE legs 744) through the soldering alloy layer. For example, the metal lead frame (e.g., the shunt sheet 750) is aligned with one or more alignment pins (e.g., the one or more alignment markers 705) on the assembly jig to allow a plurality of shunt plates (e.g., the plurality of shunt plates 754) to form contacts with corresponding TE legs (e.g., the TE legs 744), through the soldering alloy layer.
(i) performing a brazing and soldering process to form a bonding between the TE legs (e.g., the TE legs 744) and the contact regions 714 (e.g., the metal contact pads 530), and a bonding between the TE legs (e.g., the TE legs 744) and the shunt plates (e.g., the shunt plates 754). For example, the existing structure for the multi-leg package (MLP) 700 is loaded into a group loader and are subjected to the thermal treatment together in a forming gases.
(j) performing cleaning to remove residue material after the soldering process. For example, the cleaning process is performed by using hot deionized (DI) water. As a result, the metal lead frame (e.g., the shunt sheet 750) is fully attached to the TE legs (e.g., the TE legs 744), which remain bonded by the brazing alloy with the contact regions 714 (e.g., the metal contact pads 530). In one embodiment, the metal lead frame includes the plurality of shunt plates 754 that are pre-fabricated into a shunt sheet 750 by patterning. In another embodiment, the metal lead frame (e.g., the shunt sheet 750) includes a plurality of shunt plates (e.g., the plurality of shunt plates 754) that are fabricated from a whole piece of sheet conductor so that each shunt plate has at least some small tabs retained to link with its neighboring shunt plates to avoid falling apart.
(k) trimming the metal lead frame. In one embodiment, after the metal lead frame is firmly attached to the top ends of the brazed TE legs, the tabs that link a shunt plate to its neighboring shunt plates are trimmed (e.g., by laser) to clean up the separation between neighboring shunt plates and thus ensure the only electrical path between the neighboring shunt plates is to go through corresponding TE legs attached underneath. In another embodiment, after the trimming, individual shunt plates 440 each appear as a standalone piece as their mechanical contacts are only with the attachment to the corresponding TE legs 100.
(l) performing an electrical test. For example, the electrical test includes open-circuit test.

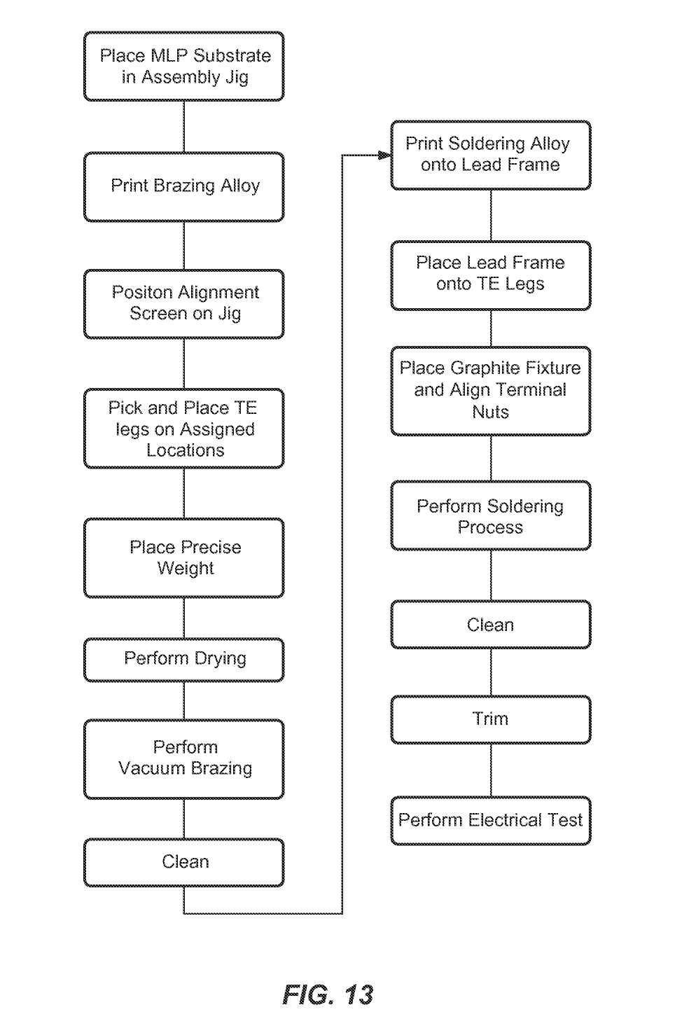

FIG. 13 is a simplified diagram showing a method of making certain components of the multi-leg package (MLP) 700 as shown in FIG. 6, FIG. 7, FIGS. 8A-8C, and/or FIG. 9 according to yet another embodiment of the present invention. This diagram is merely an example, which should not unduly limit the scope of the claims. One of ordinary skill in the art would recognize many variations, alternatives, and modifications.

As shown in FIG. 13, the method includes the following processes:
(a) placing a multi-leg package (MLP) substrate in an assembly jig. For example, the multi-leg package (MLP) substrate (e.g., the bottom contact sheet 710) is placed in the assembly jig (e.g., onto the base plate 701). In another example, the multi-leg package (MLP) substrate includes a ceramic plate (e.g., a silicon nitride ceramic plate) that is capped by copper pads (e.g., the plurality of metal contact pads 530 and 540) on two sides in mirror symmetry. In yet another example, the copper pads (e.g., the plurality of metal contact pads 530) are arranged in predetermined rows and columns, and other copper pads (e.g., the plurality of metal contact pads 540) are also arranged in corresponding predetermined rows and columns.
(b) placing a preformed alloy foil in each leg position. For example, the preformed alloy foil includes the coupling material 724 (e.g., a brazing alloy). In another example, the placement of the preformed alloy foils is performed by using the alignment screen 720.
(c) placing an alignment screen (e.g., the alignment sheet 730) to align with the assembly jig (e.g., to align with the base plate 701). For example, the alignment screen (e.g., the alignment sheet 730) is used to guide the to-be-placed TE legs (e.g., the plurality of TE legs 744).
(d) picking each TE leg and placing the TE leg in an assigned locations. For example, the picking and placing of each TE leg is performed by a bonder. In another example, the TE leg is a TE leg 744 (e.g., an N-type TE leg or a P-type TE leg). In yet another example, the TE legs are placed in multiple rows and columns on pre-assigned locations where the brazing alloy layer has been printed.
(e) placing precise weight object. In one embodiment, the TE legs (e.g., the TE legs 744) in multiple rows and columns are temporarily fixed at their locations by the paste-form bonding material during the pick and place process. For example, a precise weight object is placed onto the TE legs (e.g., the TE legs 744) to hold the TE legs in their positions. In another example, the weight object is properly aligned by placing its one or more alignment holes onto one or more alignment pins (e.g., the one or more alignment markers 705) respectively on the assembly jig.
(f) performing a drying process. In one embodiment, with the weigh object, a drying process is performed to remove moisture around the TE legs and the alloy layer.
(g) performing a vacuum brazing process. In one embodiment, after the drying process, with the weight object, the existing structure for the multi-leg package (MLP) 700 is loaded into a vacuum environment for performing a brazing process. For example, the brazing alloy melts before the TE leg 744 and the plurality of contact regions 714 (e.g., the plurality of metal contact pads 530) and subsequently forms a strong bond between the TE leg 744 and the contact regions 714.
(h) performing cleaning to remove residue material. For example, the cleaning process is performed by using hot deionized (DI) water.
(i) printing a soldering alloy onto shunt plates (e.g., the shunt plates 754) of a metal lead frame (e.g., the shunt sheet 750). For example, the soldering alloy is an eutectic alloy.
(j) placing the metal lead frame (e.g., the shunt sheet 750) onto top ends of the TE legs (e.g., the TE legs 744) through the soldering alloy on the metal lead frame. For example, the metal lead frame (e.g., the shunt sheet 750) is aligned with one or more alignment pins (e.g., the one or more alignment markers 705) on the assembly jig to allow a plurality of shunt plates (e.g., the plurality of shunt plates 754) to form contacts with corresponding TE legs (e.g., the TE legs 744) through the brazing alloy on the shunt plates.
(k) placing graphite fixture and aligning terminal nuts. In one embodiment, after the metal lead frame (e.g., the shunt sheet 750) is placed on the legs, a graphite fixture is placed on top. For example, the graphite fixture is a non-metallic structure with two predetermined through holes for placing and aligning the terminal nuts to the metal lead frame. In another example, the two terminal nuts are placed in the through holes where the terminal nuts become in contact with the metal lead frame to be soldered. In another embodiment, a precise weight object is placed on top of the graphite assembly jig. For example, the TE legs (e.g., the TE legs 744) in multiple rows and columns are temporarily fixed at their locations by the precise weight object. In another example, the weight object is properly aligned by placing its one or more alignment holes onto one or more alignment pins (e.g., the one or more alignment markers 705) respectively on the assembly jig.
(l) performing a soldering process to allow the soldering alloy to form a bonding between the TE legs (e.g., the TE legs 744) and the shunt plates (e.g., the shunt plates 754). In one embodiment, with the weigh object, the existing structure for the multi-leg package (MLP) 700 is loaded into a group loader and are subjected to the thermal treatment together in a forming gases. For example, the two terminal nuts and the TE legs are soldered simultaneously. In yet another embodiment, one or more terminal metal nuts are attached using one or more graphite fixtures to hold the one or more nuts in place. For example, one or more preformed soldering materials are placed under the one or more nuts with one or more flux materials, and reflowed together with the lead frame (e.g., the shunt sheet 750) being soldered to the TE legs (e.g., the TE legs 744).
(m) performing cleaning to remove residue material after the soldering process. For example, the cleaning process is performed by using hot deionized (DI) water. As a result, the metal lead frame (e.g., the shunt sheet 750) is fully attached to the TE legs (e.g., the TE legs 744), which remain bonded by the brazing alloy with the contact regions 714 (e.g., the metal contact pads 530). In one embodiment, the metal lead frame includes the plurality of shunt plates 754 that are prefabricated into a shunt sheet 750 by patterning. In another embodiment, the metal lead frame (e.g., the shunt sheet 750) includes a plurality of shunt plates (e.g., the plurality of shunt plates 754) that are fabricated from a whole piece of sheet conductor so that each shunt plate has at least some small tabs retained to link with its neighboring shunt plates to avoid falling apart.
(n) trimming the metal lead frame. In one embodiment, after the metal lead frame is firmly attached to the top ends of the brazed TE legs, the tabs that link a shunt plate to its neighboring shunt plates are trimmed (e.g., by laser) to clean up the separation between neighboring shunt plates and thus ensure the only electrical path between the neighboring shunt plates is to go through corresponding TE legs attached underneath. In another embodiment, after the trimming, individual shunt plates 440 each appear as a standalone piece as their mechanical contacts are only with the attachment to the corresponding TE legs 100.
(o) performing an electrical test. For example, the electrical test includes open-circuit test.

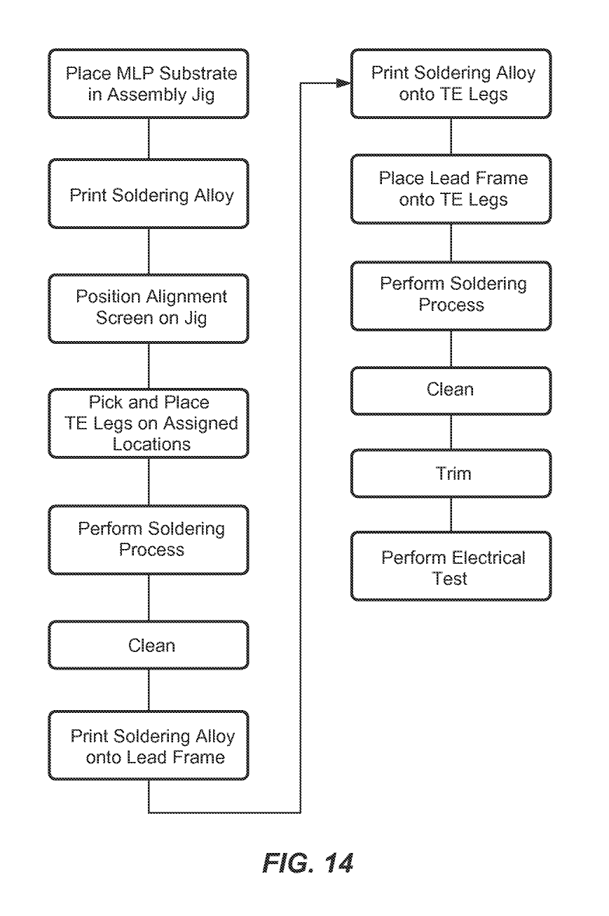

FIG. 14 is a simplified diagram showing a method of making certain components of the multi-leg package (MLP) 700 as shown in FIG. 6, FIG. 7, FIGS. 8A-8C, and/or FIG. 9 according to yet another embodiment of the present invention. This diagram is merely an example, which should not unduly limit the scope of the claims. One of ordinary skill in the art would recognize many variations, alternatives, and modifications.

As shown in FIG. 14, the method includes the following processes:
(a) placing a multi-leg package (MLP) substrate in an assembly jig. For example, the multi-leg package (MLP) substrate (e.g., the bottom contact sheet 710) is placed in the assembly jig (e.g., onto the base plate 701). In another example, the multi-leg package (MLP) substrate includes a polyimide plate that is capped by copper pads (e.g., the plurality of metal contact pads 530 and 540) on two sides in mirror symmetry. In yet another example, the copper pads (e.g., the plurality of metal contact pads 530) are arranged in predetermined rows and columns, and other copper pads (e.g., the plurality of metal contact pads 540) are also arranged in corresponding predetermined rows and columns.
(b) placing a preformed alloy foil in each leg position. For example, the preformed alloy foil includes the coupling material 724 (e.g., a soldering alloy). In another example, the soldering alloy is an eutectic alloy.
(c) placing an alignment screen (e.g., the alignment sheet 730) to align with the assembly jig (e.g., to align with the base plate 701). For example, the alignment screen (e.g., the alignment sheet 730) is used to guide the to-be-placed TE legs (e.g., the plurality of TE legs 744).
(d) picking each TE leg and placing the TE leg in an assigned locations. For example, the picking and placing of each TE leg is performed by a bonder. In another example, the TE leg is a TE leg 744 (e.g., an N-type TE leg or a P-type TE leg). In yet another example, the TE legs are placed in multiple rows and columns on pre-assigned locations where the soldering alloy layer has been printed.
(e) performing a soldering process to allow the soldering alloy to form a bonding. In one embodiment, the TE legs (e.g., the TE legs 744) in multiple rows and columns are temporarily fixed at their locations by the paste-form bonding material during the pick and place process. For example, a precise weight object is placed onto the TE legs (e.g., the TE legs 744) to hold the TE legs in their positions. In another example, the weight object is properly aligned by placing its one or more alignment holes onto one to more alignment pins (e.g., the one or more alignment markers 705) respectively on the assembly jig. In another embodiment, with the weigh object, a drying process is performed to remove moisture around the TE legs and the alloy layer. In yet another embodiment, after the drying process, with the weigh object, the existing structure for the multi-leg package (MLP) 700 is loaded into a group loader and are subjected to the thermal treatment together in a forming gases.
(f) performing cleaning to remove residue material after the soldering process is completed and the weigh object is removed. For example, the cleaning process is performed by using hot deionized (DI) water.
(g) printing a soldering alloy onto shunt plates (e.g., the shunt plates 754) of a metal, lead frame (e.g., the shunt sheet 750). For example, the soldering alloy is an eutectic alloy.
(h) placing a soldering alloy layer onto top ends of the TE legs (e.g., the TE legs 744). For example, the soldering alloy is configured to bond other one or more materials on top of the TE legs (e.g., the TE legs 744) bonded to the underneath contact regions 714 (e.g., the metal contact pads 530).
(i) placing the metal lead frame (e.g., the shunt sheet 750) onto top ends of the TE legs (e.g., the TE legs 744) through the soldering alloy on the metal lead frame and the soldering alloy layer onto top ends of the TE legs (e.g., the TE legs 744). For example, the metal lead frame (e.g., the shunt sheet 750) is aligned with one or more alignment pins (e.g., the one or more alignment markers 705) on the assembly jig to allow a plurality of shunt plates (e.g., the plurality of shunt plates 754) to form contacts with corresponding TE legs (e.g., the TE legs 744).
(j) performing a soldering process to allow the soldering alloy on the metal lead frame and the soldering alloy layer onto top ends of the TE legs to form a bonding between the TE legs (e.g., the TE legs 744) and the shunt plates (e.g., the shunt plates 754). In one embodiment, after the metal lead frame (e.g., the shunt sheet 750) is placed on the legs, a graphite fixture is placed on top. For example, the graphite fixture is a non-metallic structure with two predetermined through holes for placing and aligning the terminal nuts to the metal lead frame. In another example, the two terminal nuts are placed in the through holes where the terminal nuts become in contact with the metal lead frame to be soldered. In another embodiment, a precise weight object is placed on top of the graphite assembly jig. For example, the TE legs (e.g., the TE legs 744) in multiple rows and columns are temporarily fixed at their locations by the precise weight object. In another example, the weight object is properly aligned by placing its one or more alignment holes onto one or more alignment pins (e.g., the one or more alignment markers 705) respectively on the assembly jig. In yet another embodiment, with the weigh object, the existing structure for the multi-leg package (MLP) 700 is loaded into a group loader and are subjected to the thermal treatment together in a forming gases. For example, the two terminal nuts and the TE legs are soldered simultaneously.
(k) performing cleaning to remove residue material after the soldering process. For example, the cleaning process is performed by using hot deionized (DI) water. As a result, the metal lead frame (e.g., the shunt sheet 750) is fully attached to the TE legs (e.g., the TE legs 744), which remain bonded with the contact regions 714 (e.g., the metal contact pads 530). In one embodiment, the metal lead frame includes the plurality of shunt plates 754 that are prefabricated into a shunt sheet 750 by patterning. In another embodiment, the metal lead frame (e.g., the shunt sheet 750) includes a plurality of shunt plates (e.g., the plurality of shunt plates 754) where each shunt plate has at least some small tabs to link with its neighboring shunt plates to avoid falling apart.
(l) trimming the metal lead frame. In one embodiment, after the metal lead frame is firmly attached to the top ends of the TE legs, the tabs that link a shunt plate to its neighboring shunt plates are trimmed (e.g., by laser) to clean up the separation between neighboring shunt plates and thus ensure the only electrical path between the neighboring shunt plates is to go through corresponding TE legs attached underneath. In another embodiment, after the trimming, individual shunt plates 440 each appear as a standalone piece as their mechanical contacts are only with the attachment to the corresponding TE legs 100.
(m) performing an electrical test. For example, the electrical test includes open-circuit test.

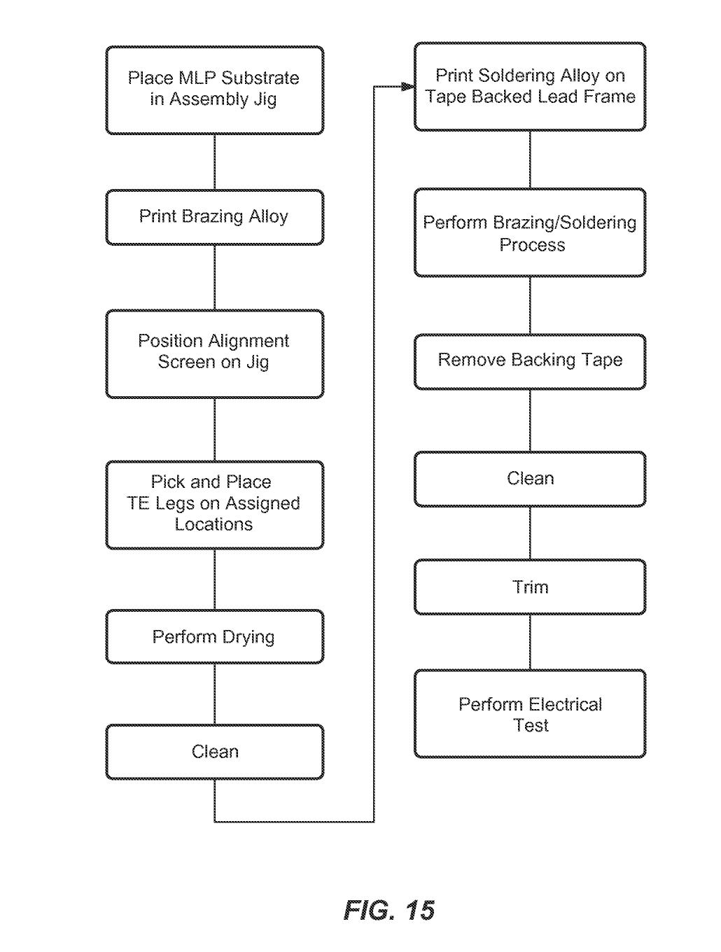

FIG. 15 is a simplified diagram showing a method of making certain components of the multi-leg package (MLP) 700 as shown in FIG. 6, FIG. 7, FIGS. 8A-8C, and/or FIG. 9 according to yet another embodiment of the present invention. This diagram is merely an example, which should not unduly limit the scope of the claims. One of ordinary skill in the art would recognize many variations, alternatives, and modifications.

As shown in FIG. 15, the method includes the following processes:
(a) placing a multi-leg package (MLP) substrate in an assembly jig. For example, the multi-leg package (MLP) substrate (e.g., the bottom contact sheet 710) is placed in the assembly jig (e.g., onto the base plate 701). In another example, the multi-leg package (MLP) substrate includes a ceramic plate (e.g., a silicon nitride ceramic plate) and/or a polyimide plate, which is capped by copper pads (e.g., the plurality of metal contact pads 530 and 540) on two sides in mirror symmetry. In yet another example, the copper pads (e.g., the plurality of metal contact pads 530) are arranged in predetermined rows and columns, and other copper pads (e.g., the plurality of metal contact pads 540) are also arranged in corresponding predetermined rows and columns.
(b) placing a preformed alloy foil in each leg position. For example, the preformed alloy foil includes the coupling material 724 (e.g., a brazing alloy). In another example, the placement of the preformed alloy foils is performed by using the alignment screen 720.
(c) placing an alignment screen (e.g., the alignment sheet 730) to align with the assembly jig (e.g., to align with the base plate 701). For example, the alignment screen (e.g., the alignment sheet 730) is used to guide the to-be-placed TE legs (e.g., the plurality of TE legs 744).
(d) picking each TE leg and placing the TE leg in an assigned locations. For example, the picking and placing of each TE leg is performed by a bonder. In another example, the TE leg is a TE leg 744 (e.g., an N-type TE leg or a P-type TE leg). In yet another example, the TE legs are placed in multiple rows and columns on pre-assigned locations where the brazing alloy layer has been printed.
(e) performing a drying process. In one embodiment, the TE legs (e.g., the TE legs 744) in multiple rows and columns are temporarily fixed at their locations by the paste-form bonding material during the pick and place process. For example, a precise weight object is placed onto the TE legs (e.g., the TE legs 744) to hold the TE legs in their positions. In another example, the weight object is properly aligned by placing its one or more alignment holes onto one or more alignment pins (e.g., the one or more alignment markers 705) respectively on the assembly jig. In another embodiment, with the weigh object, a drying process is performed to remove moisture around the TE legs and the alloy layer (e.g., the brazing alloy).
(f) performing cleaning to remove residue material. For example, the cleaning process is performed by using hot deionized (DI) water.
(g) printing a soldering alloy onto shunt plates (e.g., the shunt plates 754) of a tape-backed lead frame (e.g., the shunt sheet 750). In one embodiment, the soldering alloy is an eutectic alloy. In another embodiment, the tape-backed lead frame (e.g., the shunt sheet 750) is placed onto top ends of the TE legs (e.g., the TE legs 744) through the soldering alloy on the lead frame. For example, the lead frame (e.g., the shunt sheet 750) is aligned with one or more alignment pins (e.g., the one or more alignment markers 705) on the assembly jig to allow a plurality of shunt plates (e.g., the plurality of shunt plates 754) to form contacts with corresponding TE legs (e.g., the TE legs 744) through the brazing alloy on the shunt plates.
(h) performing a brazing and soldering process to form a bonding between the TE legs (e.g., the TE legs 744) and the contact regions 714 (e.g., the metal contact pads 530), and a bonding between the TE legs (e.g., the TE legs 744) and the shunt plates (e.g., the shunt plates 754).

In one embodiment, after the tape-backed lead frame (e.g., the shunt sheet 750) is placed on the legs, a graphite fixture is placed on top. For example, the graphite fixture is a non-metallic structure with two predetermined through holes for placing and aligning the terminal nuts to the tape-backed lead frame. In another example, the two terminal nuts are placed in the through holes where the terminal nuts become in contact with the tape-backed lead frame to be soldered. In another embodiment, a precise weight object is placed on top of the graphite assembly jig. For example, the TE legs (e.g., the TE legs 744) in multiple rows and columns are temporarily fixed at their locations by the precise weight object. In another example, the weight object is properly aligned by placing its one or more alignment holes onto one or more alignment pins (e.g., the one or more alignment markers 705) respectively on the assembly jig. In yet another embodiment, with the weigh object, the existing structure for the multi-leg package (MLP) 700 is loaded into a group loader and are subjected to the thermal treatment together in a forming gases. For example, the two terminal nuts and the TE legs are soldered simultaneously. In yet another embodiment, one or more terminal metal nuts are attached using one or more graphite fixtures to hold the one or more nuts in place. For example, one or more preformed soldering materials are placed under the one or more nuts with one or more flux materials, and reflowed together with the tape-backed lead frame (e.g., the shunt sheet 750) being soldered to the TE legs (e.g., the TE legs 744).
(i) removing backing tape from the tape-backed lead frame.
(j) performing cleaning to remove residue material after the soldering process. For example, the cleaning process is performed by using hot deionized (DI) water. As a result, the lead frame (e.g., the shunt sheet 750) is fully attached to the TE legs (e.g., the TE legs 744), which remain bonded by the brazing alloy with the contact regions 714 (e.g., the metal contact pads 530). In one embodiment, the lead frame includes the plurality of shunt plates 754 that are prefabricated into a shunt sheet 750 by patterning. In another embodiment, the lead frame (e.g., the shunt sheet 750) includes a plurality of shunt plates (e.g., the plurality of shunt plates 754) that are fabricated from a whole piece of sheet conductor so that each shunt plate has at least some small tabs retained to link with its neighboring shunt plates to avoid falling apart.
(k) trimming the lead frame. In one embodiment, after the lead frame is firmly attached to the top ends of the brazed TE legs, the tabs that link a shunt plate to its neighboring shunt plates are trimmed (e.g., by laser) to clean up the separation between neighboring shunt plates and thus ensure the only electrical path between the neighboring shunt plates is to go through corresponding TE legs attached underneath. In another embodiment, after the trimming, individual shunt plates 440 each appear as a standalone piece as their mechanical contacts are only with the attachment to the corresponding TE legs 100.
(l) performing an electrical test. For example, the electrical test includes open-circuit test.

As discussed above and further emphasized here, FIGS. 11-15 are merely examples, which should not unduly limit the scope of the claims. One of ordinary skill in the art would recognize many variations, alternatives, and modifications. For example, the metal lead frame is replaced by a lead frame that is made from a standalone non-conductive thin film (e.g., a standalone polyimide film) with embedded metal foil (e.g., copper foil) in predetermined circuit patterns; therefore, the process of trimming the lead frame is skipped. In another example, the process of performing an electrical test is skipped. In another example, all the processing tools, such as alignment screens, alignment sheets, and/or weight objects, are used with proper alignment in reliance on the one or more alignment pins (e.g., the one or more built-in alignment markers 705) to ensure corresponding elements in the multi-leg package (MLP) (e.g., the multi-leg package 700) are placed in proper positions. In yet another example, the weight object includes two holes, one of which has a round shape matching with the round alignment pin (e.g., a alignment marker 705) at one corner and the other of which has a slightly larger square-shape to allow certain level of flexibility in terms of difference in thermal expansion coefficient between the weight object and the MLP base structure (e.g., the contact sheet 710, the base structure 510).

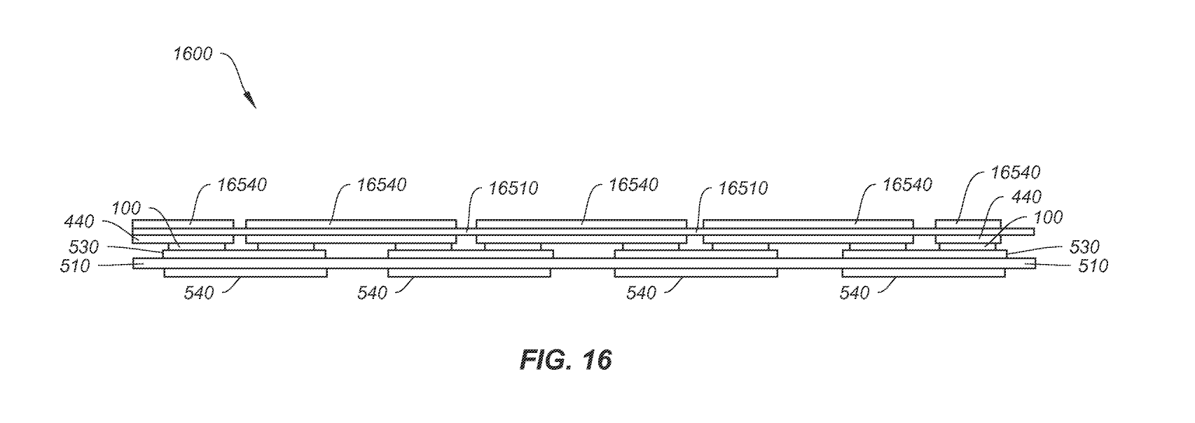

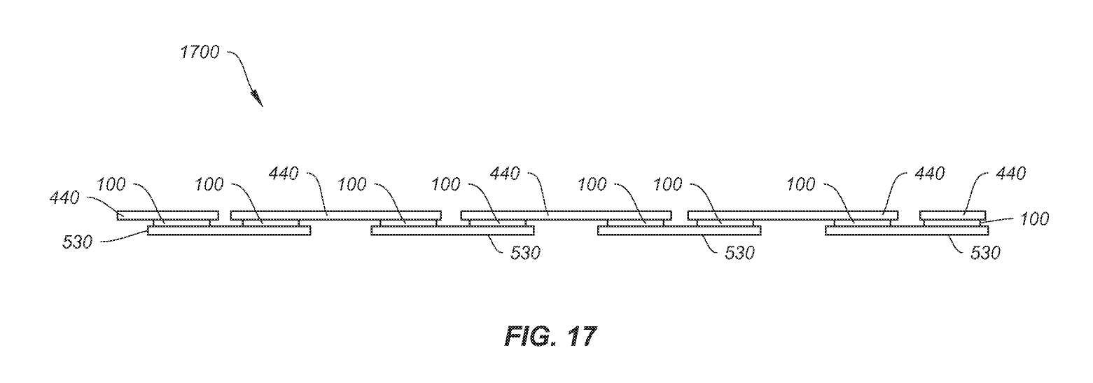

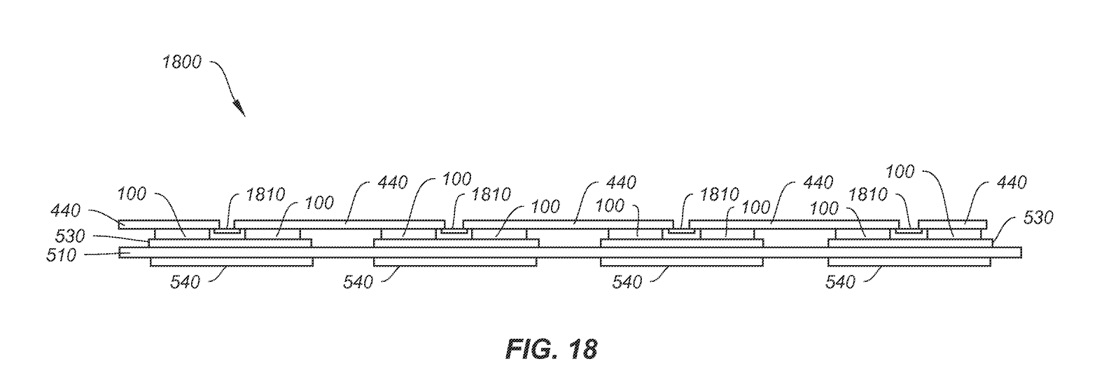

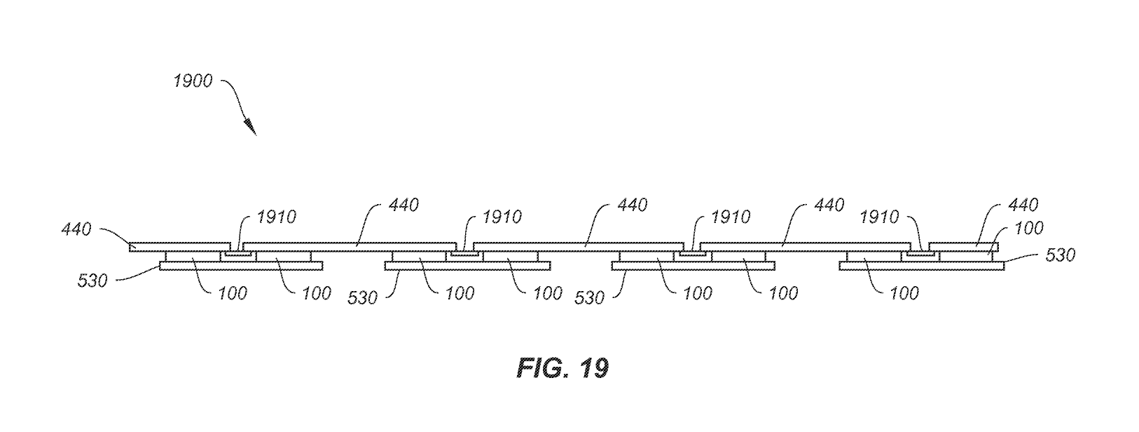

As discussed above and further emphasized here, FIGS. 6-9 are merely examples, which should not unduly limit the scope of the claims. One of ordinary skill in the art would recognize many variations, alternatives, and modifications. For example, the plurality of shunt plates 440 (e.g., the plurality of shunt plates 754) are not prefabricated into a metal lead frame (e.g., a shunt sheet 750), but instead, the plurality of shunt plates 440 (e.g., the plurality of shunt plates 754) are attached to a ceramic base substrate, as shown in FIG. 16. In another example, the multi-leg package (MLP) does not include the base substrate 510 (e.g., the contact sheet 710) and/or the array of metal contact pads 540, but instead, the array of metal contact pads 530 (e.g., the array of contact regions 714) are prefabricated into a metal lead frame, as shown in FIG. 17. In yet another example, the metal lead frame (e.g., the shunt sheet 750) is replaced by a polyimide lead frame, as shown in FIGS. 10 and 18. In yet another example, the multi-leg package (MLP) does not include the base substrate 510 (e.g., the contact sheet 710) and/or the array of metal contact pads 540, but instead, the array of metal contact pads 530 (e.g., the array of contact regions 714) are prefabricated into a metal lead frame, and another metal lead frame (e.g., the shunt sheet 750) is replaced by a polyimide lead frame, as shown in FIGS. 10 and 19.

FIG. 16 is a simplified diagram showing certain components of a multi-leg package (MLP) according to another embodiment of the present invention. This diagram is merely an example, which should not unduly limit the scope of the claims. One of ordinary skill in the art would recognize many variations, alternatives, and modifications.

As shown in FIG. 16, a multi-leg package (MLP) 1600 includes a base substrate 510 (e.g., the contact sheet 710), attached to an array of metal contact pads 530 (e.g., an array of contact regions 714) on the front-side surface and attached to another array of metal contact pads 540 on the backside surface substantially in a mirror symmetry. In one embodiment, the base substrate 510 is made of a material that is an electrical insulator but a good thermal conductor. For example, the base substrate 510 is made of a ceramic material. In another embodiment, the metal contact pads 530 and the metal contact pads 540 are made of a material that is both thermally and electrically conductive. For example, the metal contact pads 530 and the metal contact pads 540 are made of copper. In another example, the metal contact pads 530 are arranged in multiple rows and columns and separated by a spacing from each other. In yet another example, the metal contact pads 540 are arranged in multiple rows and columns and separated by a spacing from each other.

Also as shown in FIG. 16, the multi-leg package (MLP) 1600 further includes a plurality of TE legs 100 (e.g., the plurality of TE legs 744) that are aligned with the metal contact pads 530 on the base substrate 510 respectively. In one embodiment, the plurality of TE legs 100 are arranged in a predetermined pattern of rows and columns so that each leg is separated from another and each metal contact pad 530 is aligned to support at least two TE legs 100. For example, these two TE legs 100 include an N-type TE leg 210 and a P-type TE leg 220. In another example, in each row, the TE legs 100 are arranged in a series with an N-type and P type alternating order. In another embodiment, each row of TE legs 100 is grouped with a redundant row of TE legs 100 that has exactly the same N-type and P-type alternating order. For example, two redundant pairs of N-type and P-type TE legs 100 have parallel electrical paths. In another example, the next two rows of TE legs 100, one being redundant to the other, have an N-type and P-type alternating order that is shifted one leg position compared to the first two rows.

Further as shown in FIG. 16, the multi-leg package (MLP) 1600 also includes a plurality of shunt plates 440 (e.g., a plurality of shunt plates 754) on the plurality of TE legs 100 (e.g., the plurality of TE legs 744). In one embodiment, the plurality of shunt plates 440 (e.g., the plurality of shunt plates 754) are attached to the plurality of TE legs 100 on their back surface, and attached to a base substrate 16510 on their front-side surfaces. For example, the base substrate 16510 is attached to the plurality of shunt plates 440 (e.g., the plurality of shunt plates 754) on the back surface, and attached to another plurality of shunt plates 16540 on the backside surface substantially in a mirror symmetry.

In another embodiment, the base substrate 16510 is made of a material that is an electrical insulator but a good thermal conductor. For example, the base substrate 16510 is made of a ceramic material. In yet another embodiment, the shunt plates 440 and the shunt plates 16540 are made of a material that is both thermally and electrically conductive. For example, the shunt plates 440 and the shunt plates 16540 are made of copper. In another example, the shunt plates 440 are arranged in multiple rows and columns and separated by a spacing from each other. In yet another example, the shunt plates 16540 are arranged in multiple rows and columns and separated by a spacing from each other.

In yet another embodiment, each TE leg 100 has its first end placed on a metal contact pad 530 and has its second end attached to a shunt plate 440 (e.g., a sheet conductor). For example, the plurality of shunt plates 440 (e.g., the plurality of shunt plates 754) complete an electrical path throughout all of the plurality of TE legs 100 (e.g., the plurality of TE legs 744) until reaching the end terminals (e.g., the electrical leads 810 and 820). In another example, along any row direction, the electrical path is a daisy-chain connection by going from a first shunt plate 440 down to a first TE leg 100, through a metal contact pad 530 that supports the first TE leg 100, to a second TE leg that of a different type from the first TE leg 100, and then up to a second shunt plate 440 that is next to the first shunt plate 440 but have no direct electrical connection to avoid undesirable shorting from the first shunt plate 440 to the second shunt plate 440

FIG. 17 is a simplified diagram showing certain components of a multi-leg package (MLP) according to yet another embodiment of the present invention. This diagram is merely an example, which should not unduly limit the scope of the claims. One of ordinary skill in the art would recognize many variations, alternatives, and modifications.

As shown in FIG. 17, the multi-leg package (MLP) 700 includes an array of metal contact pads 530 (e.g., an array of contact regions 714). In one embodiment, the array of metal contact pads 530 (e.g., the array of contact regions 714) are prefabricated into a metal lead frame. For example, the metal lead frame includes multiple metal contact pads 530 mechanically tabbing together by one or more metal components (e.g., one or more copper components). In another embodiment, the metal contact pads 530 are made of a material that is both thermally and electrically conductive. For example, the metal contact pads 530 are made of copper. In another example, the metal contact pads 530 are arranged in multiple rows and columns and separated by a spacing from each other. In yet another example, after the metal lead frame is attached to a plurality of TE legs 100 (e.g., the plurality of TE legs 744), mechanical connections that have existed initially are trimmed to avoid undesirable shorting from one metal contact pad 530 to another metal contact pad 530. In yet another example, after the trimming, the individual metal contact pads 530 each appear as a standalone piece as their mechanical contacts are only with the attachment to the corresponding TE legs 100.

Also as shown in FIG. 17, the multi-leg package (MLP) 1700 further includes the plurality of TE legs 100 (e.g., the plurality of TE legs 744) that are aligned with the metal contact pads 530 respectively. In one embodiment, the plurality of TE legs 100 are arranged in a predetermined pattern of rows and columns so that each leg is separated from another and each metal contact pad 530 is aligned to support at least two TE legs 100. For example, these two TE legs 100 include an N-type TE leg 210 and a P-type TE leg 220. In another example, in each row, the TE legs 100 are arranged in a series with an N-type and P type alternating order. In another embodiment, each row of TE legs 100 is grouped with a redundant row of TE legs 100 that has exactly the same N-type and P-type alternating order. For example, two redundant pairs of N-type and P-type TE legs 100 have parallel electrical paths. In another example, the next two rows of TE legs 100, one being redundant to the other, have an N-type and P-type alternating order that is shifted one leg position compared to the first two rows.

Further as shown in FIG. 17, the multi-leg package (MLP) 1700 also includes a plurality of shunt plates 440 (e.g., a plurality of shunt plates 754) on the plurality of TE legs 100 (e.g., the plurality of TE legs 744). In one embodiment, the plurality of shunt plates 440 (e.g., the plurality of shunt plates 754) are prefabricated into another metal lead frame (e.g., a shunt sheet 750). For example, the metal lead frame (e.g., a shunt sheet 750) includes multiple shunt plates 440 mechanically tabbing together by one or more metal components (e.g., one or more copper components). In another example, the metal lead frame is aligned with the plurality of TE legs 100 (e.g., the plurality of TE legs 744) in their predetermined positions on individual metal contact pads 530, so that each shunt plate 440 is in position to form an electrical coupling with four TE legs 100 from two successive rows and two successive columns. In yet another example, after the metal lead frame (e.g., a shunt sheet 750) is placed onto the plurality of TE legs 100 (e.g., the plurality of TE legs 744), mechanical connections that have existed initially are trimmed to avoid undesirable shorting from one shunt plate 440 to another shunt plate 440. In yet another example, after the trimming, the individual shunt plates 440 each appear as a standalone piece as their mechanical contacts are only with the attachment to the corresponding TE legs 100.

In another embodiment, each TE leg 100 has its first end placed on a metal contact pad 530 and has its second end attached to a shunt plate 440 (e.g., a sheet conductor). For example, the plurality of shunt plates 440 (e.g., the plurality of shunt plates 754) complete an electrical path throughout all of the plurality of TE legs 100 (e.g., the plurality of TE legs 744) until reaching the end terminals (e.g., the electrical leads 810 and 820). In another example, along any row direction, the electrical path is a daisy-chain connection by going from a first shunt plate 440 down to a first TE leg 100, through a metal contact pad 530 that supports the first TE leg 100, to a second TE leg that of a different type from the first TE leg 100, and then up to a second shunt plate 440 that is next to the first shunt plate 440 but have no direct mechanical connection after the mechanical connections that have existed initially in the metal lead frame are trimmed to avoid undesirable shorting from one shunt plate 440 to another shunt plate 440.

FIG. 18 is a simplified diagram showing certain components of a multi-leg package (MLP) according to yet another embodiment of the present invention. This diagram is merely an example, which should not unduly limit the scope of the claims. One of ordinary skill in the art would recognize many variations, alternatives, and modifications.

As shown in FIG. 18, the multi-leg package (MLP) 1800 includes a base substrate 510 (e.g., the contact sheet 710), attached to an array of metal contact pads 530 (e.g., an array of contact regions 714) on the front-side surface and another array of metal contact pads 540 on the backside surface substantially in a mirror symmetry. In one embodiment, the base substrate 510 is made of a material that is an electrical insulator but a good thermal conductor. For example, the base substrate 510 is made of a ceramic material. In another embodiment, the metal contact pads 530 and the metal contact pads 540 are made of a material that is both thermally and electrically conductive. For example, the metal contact pads 530 and the metal contact pads 540 are made of copper. In another example, the metal contact pads 530 are arranged in multiple rows and columns and separated by a spacing from each other. In yet another example, the metal contact pads 540 are arranged in multiple rows and columns and separated by a spacing from each other.

Also as shown in FIG. 18, the multi-leg package (MLP) 1800 further includes a plurality of TE legs 100 (e.g., the plurality of TE legs 744) that are aligned with the metal contact pads 530 on the base substrate 510 respectively. In one embodiment, the plurality of TE legs 100 are arranged in a predetermined pattern of rows and columns so that each leg is separated from another and each metal contact pad 530 is aligned to support at least two TE legs 100. For example, these two TE legs 100 include an N-type TE leg 210 and a P-type TE leg 220. In another example, in each row, the TE legs 100 are arranged in a series with an N-type and P type alternating order. In another embodiment, each row of TE legs 100 is grouped with a redundant row of TE legs 100 that has exactly the same N-type and P-type alternating order. For example, two redundant pairs of N-type and P-type TE legs 100 have parallel electrical paths. In another example, the next two rows of TE legs 100, one being redundant to the other, have an N-type and P-type alternating order that is shifted one leg position compared to the first two rows.

Further as shown in FIG. 18, the multi-leg package (MLP) 1800 also includes a plurality of shunt plates 440 (e.g., a plurality of shunt plates 754) on the plurality of TE legs 100 (e.g., the plurality of TE legs 744). In one embodiment, the plurality of shunt plates 440 (e.g., the plurality of shunt plates 754) are prefabricated into a polyimide lead frame. For example, the polyimide lead frame is made from a standalone polyimide film. In another example, the polyimide lead frame includes multiple shunt plates 440 (e.g., embedded metal foils) mechanically tabbing together by one or more polyimide components 1810 (e.g., one or more polyimide tabs that link the multiple shunt plates 440). In yet another example, the one or more polyimide components 1810 are made of Kapton. In another embodiment, the polyimide lead frame is aligned with the plurality of TE legs 100 (e.g., the plurality of TE legs 744) in their predetermined positions on individual metal contact pads 530, so that each shunt plate 440 is in position to form an electrical coupling with four TE legs 100 from two successive rows and two successive columns.

In yet another embodiment, each TE leg 100 has its first end placed on a metal contact pad 530 and has its second end attached to a shunt plate 440 (e.g., a sheet conductor). For example, the plurality of shunt plates 440 (e.g., the plurality of shunt plates 754) complete an electrical path throughout all of the plurality of TE legs 100 (e.g., the plurality of TE legs 744) until reaching the end terminals (e.g., the electrical leads 810 and 820). In another example, along any row direction, the electrical path is a daisy-chain connection by going from a first shunt plate 440 down to a first TE leg 100, through a metal contact pad 530 that supports the first TE leg 100, to a second TE leg that of a different type from the first TE leg 100, and then up to a second shunt plate 440 that is next to the first shunt plate 440 but have no direct electrical connection to avoid undesirable shorting from the first shunt plate 440 to the second shunt plate 440. In yet another embodiment, the multi-leg package (MLP) 1800 can be applied to a thermal junction with the hot-side temperature being higher than 250° C. For example, a polyimide lead frame that includes the plurality of shunt plates 440 is configured to tolerate a temperature of the base substrate 510 on the hot side even if the temperature of the base structure 510 is higher than 250° C.

FIG. 19 is a simplified diagram showing certain components of a multi-leg package (MLP) according to yet another embodiment of the present invention. This diagram is merely an example, which should not unduly limit the scope of the claims. One of ordinary skill in the art would recognize many variations, alternatives, and modifications.

As shown in FIG. 19, the multi-leg package (MLP) 1900 includes an array of metal contact pads 530 (e.g., an array of contact regions 714). In one embodiment, the array of metal contact pads 530 (e.g., the array of contact regions 714) are prefabricated into a metal lead frame. For example, the metal lead frame includes multiple metal contact pads 530 mechanically tabbing together by one or more metal components (e.g., one or more copper components). In another embodiment, the metal contact pads 530 are made of a material that is both thermally and electrically conductive. For example, the metal contact pads 530 are made of copper. In another example, the metal contact pads 530 are arranged in multiple rows and columns and separated by a spacing from each other. In yet another example, after the metal lead frame is attached to a plurality of TE legs 100 (e.g., the plurality of TE legs 744), mechanical connections that have existed initially are trimmed to avoid undesirable shorting from one metal contact pad 530 to another metal contact pad 530. In yet another example, after the trimming, the individual metal contact pads 530 each appear as a standalone piece as their mechanical contacts are only with the attachment to the corresponding TE legs 100.

Also as shown in FIG. 19, the multi-leg package (MLP) 1900 further includes the plurality of TE legs 100 (e.g., the plurality of TE legs 744) that are aligned with the metal contact pads 530 respectively. In one embodiment, the plurality of TE legs 100 are arranged in a predetermined pattern of rows and columns so that each leg is separated from another and each metal contact pad 530 is aligned to support at least two TE legs 100. For example, these two TE legs 100 include an N-type TE leg 210 and a P-type TE leg 220. In another example, in each row, the TE legs 100 are arranged in a series with an N-type and P type alternating order. In another embodiment, each row of TE legs 100 is grouped with a redundant row of TE legs 100 that has exactly the same N-type and P-type alternating order. For example, two redundant pairs of N-type and P-type TE legs 100 have parallel electrical paths. In another example, the next two rows of TE legs 100, one being redundant to the other, have an N-type and P-type alternating order that is shifted one leg position compared to the first two rows.

Further as shown in FIG. 19, the multi-leg package (MLP) 1900 also includes a plurality of shunt plates 440 (e.g., a plurality of shunt plates 754) on the plurality of TE legs 100 (e.g., the plurality of TE legs 744). In one embodiment, the plurality of shunt plates 440 (e.g., the plurality of shunt plates 754) are prefabricated into a polyimide lead frame. For example, the polyimide lead frame is made from a standalone polyimide film. In another example, the polyimide lead frame includes multiple shunt plates 440 (e.g., embedded metal foils) mechanically tabbing together by one or more polyimide components 1910 (e.g., one or more polyimide tabs that link the multiple shunt plates 440). In yet another example, the one or more polyimide components 1910 are made of Kapton. In another embodiment, the polyimide lead frame is aligned with the plurality of TE legs 100 (e.g., the plurality of TE legs 744) in their predetermined positions on individual metal contact pads 530, so that each shunt plate 440 is in position to form an electrical coupling with four TE legs 100 from two successive rows and two successive columns.

In yet another embodiment, each TE leg 100 has its first end placed on a metal contact pad 530 and has its second end attached to a shunt plate 440 (e.g., a sheet conductor). For example, the plurality of shunt plates 440 (e.g., the plurality of shunt plates 754) complete an electrical path throughout all of the plurality of TE legs 100 (e.g., the plurality of TE legs 744) until reaching the end terminals (e.g., the electrical leads 810 and 820). In another example, along any row direction, the electrical path is a daisy-chain connection by going from a first shunt plate 440 down to a first TE leg 100, through a metal contact pad 530 that supports the first TE leg 100, to a second TE leg that of a different type from the first TE leg 100, and then up to a second shunt plate 440 that is next to the first shunt plate 440 but have no direct electrical connection to avoid undesirable shorting from the first shunt plate 440 to the second shunt plate 440. In yet another embodiment, the multi-leg package (MLP) 1900 can be applied to a thermal junction with the hot-side temperature being higher than 250° C. For example, a polyimide lead frame that includes the plurality of shunt plates 440 is configured to tolerate a temperature of the metal contact pads 530 on the hot side even if the temperature of the metal contact pads 530 is higher than 250° C.

According to another embodiment, a multi-leg package thermoelectric module assembly includes a substrate including a base plate and an array of pads arranged in rows and columns and attached on both sides of the base plate in a mirror symmetry. The base plate is a thermal conductor but an electrical insulator and each pad is an electrical/thermal dual conductor spaced from each other. Additionally, the module assembly includes a plurality of thermoelectric legs being separately placed in rows and columns on the array of pads. Each pad is configured to support at least two thermoelectric legs. Furthermore, the module assembly includes a lead frame comprising a plurality of sheet conductors. Each sheet conductor is configured according to a predetermined pattern to align and form electrical coupling with four thermoelectric legs from two successive rows and two successive columns, and each of the four thermoelectric legs has its first end including bonding metals coupled with one of four separate pads via a braze alloy and its second end attached with the sheet conductor. Each row of the plurality of thermoelectric legs is arranged alternatively in N and P types semiconductor doping characteristics and two legs in a same row/column among the four thermoelectric legs attached under each sheet conductor are same/different type.

For example, the base plate is a ceramic material selected from Si₃N₄ and each pad is made of copper. In another example, the substrate includes multiple scribed lines cut partially into the base plate at locations between two neighbor columns/rows of the array of pads for every other few rows/columns of pads. In yet another example, the braze alloy material is printed on the array of pads for bonding with the first end of each of plurality of thermoelectric legs. In yet another example, the braze alloy material is configured to form a peritectoid compound with the pad and bonding metals on the thermoelectric legs, and the peritectoid compound is susceptible to operation temperature at least 650° C. In yet another example, the multi-leg package thermoelectric module assembly further includes a soldering alloy material being printed on the second end of each of the plurality of thermoelectric legs for bonding with the lead frame.

In yet another example, the thermoelectric leg includes a bulk-sized thermoelectric material made by one selected from Bi2Te3, Mg₂Si, MnSi₂, PbTe, silicon-based nanostructured materials, sintered nano-composite materials, and half heusler materials. In yet another example, the thermoelectric leg includes a thermoelectric material capable for application with a hot-side temperature over 600° C. In yet another example, the lead frame is a copper-based sheet material comprising thinned sheet members around edges of each sheet conductor to couple one or more neighboring sheet conductor. In yet another example, the lead frame includes copper foil embedded in a high-temperature polyimide film. In yet another example, the lead frame includes a patterned copper foil attached to one side of a ceramic substrate and another copper foil overlying entire area of another side of the ceramic substrate. In yet another example, each N/P type thermoelectric leg of the plurality of thermoelectric legs connects to a neighboring P/N type thermoelectric leg electrically in series. In yet another example, each N/P type thermoelectric leg of the plurality of thermoelectric legs shares with another redundant N/P type thermoelectric leg electrically in parallel. In yet another example, the lead frame includes two global leads for external electrical connection.

According to yet another embodiment, a method for assembling a multi-leg package thermoelectric module includes providing an assembly base structure. The assembly base structure includes at least two alignment pins located on two corner regions. Additionally, the method includes placing an MLP substrate in the assembly base structure. The MLP substrate includes an array of conductive pads arranged in rows and columns separated each other by a spacing. Moreover, the method includes applying a braze alloy layer on each conductive pad at least partially, disposing a plurality of thermoelectric legs to separate positions in rows and columns to align with the array of conductive pads using an alignment screen so that each pad is at least attached with two thermoelectric legs, operably fixing the plurality of thermoelectric legs in their positions via the braze alloy layer, applying a soldering alloy layer over each of the plurality of thermoelectric legs, and placing a lead frame over the plurality of thermoelectric legs. The lead frame includes a plurality of sheet conductors at least partially connected to each other. Also, the method includes operably fixing the lead frame in a predetermined position so that each sheet conductor aligns and forms an electrical coupling via the soldering alloy layer with four thermoelectric legs from two successive rows and two successive columns while being respectively attached with four separate conductive pads and optionally trimming the lead frame so that each sheet conductor is free of other mechanical contact with its neighboring sheet conductor but having a properly electrical connection only through one or two thermoelectric legs and corresponding conductive pads that support the one or two thermoelectric legs.

For example, the assembly base structure includes a recessed top region configured to load the MLP substrate so that the conductive pads have a level slightly above a surface level of the assembly base structure. In another example, each of the two alignment pins has a vertical height above the base structure and a round shape in cross-section. In yet another example, the MLP substrate comprises a ceramic material that is an electrical insulator but a good thermal conductor. In yet another example, the MLP substrate further includes another array of conductive pads formed at the other side of the ceramic material in positions mirroring the array of conductive pads.

In yet another example, the process of applying a braze alloy layer includes printing over a pre-set screen aligned with the array of conductive pads. In yet another example, the process of disposing a plurality of thermoelectric legs comprises applying a die bonder to place a plurality of the thermoelectric legs at once. In yet another example, the process of disposing a plurality of thermoelectric legs includes placing a first row of thermoelectric legs characterized by an alternative N-type and P-type order in association to a series of sheet conductors. In yet another example, the process of disposing a plurality of thermoelectric legs includes placing a redundant row of thermoelectric legs having the same an alternative N-type and P-type order in association to the first row. In yet another example, the process of disposing a plurality of thermoelectric legs includes placing at least one column of thermoelectric legs attached to a half-sized sheet conductor for connecting thermoelectric legs in different row other than the redundant row. In yet another example, the process of disposing a plurality of thermoelectric legs includes placing a redundant row of legs for each row.

In yet another example, the process of operably fixing the plurality of thermoelectric legs includes temporarily fixing each leg on a conductive pad using a pre-disposed bonding material, placing a precise weight member on the temporarily fixed leg, drying the bonding material, and performing high-vacuum braze process to allow the bonding material of each leg to react with the braze alloy layer to fix each leg on the conductive pad. The precise weight member includes a first through-hole being round in shape matching the alignment pin and a second hole being square in shape having slightly bigger size than the alignment pin. In yet another example, the process of placing a lead frame is assisted via an alignment using two holes within the lead frame matching the two alignment pins on the base structure.

According to yet another embodiment, a method for assembling a multi-leg package thermoelectric module includes providing an assembly base structure. The assembly base structure includes at least two alignment pins located on two corner regions.

Additionally, the method includes placing an MLP substrate in the assembly base structure. The MLP substrate includes an array of conductive pads arranged in rows and columns separated each other by a spacing. Moreover, the method includes applying a first braze alloy layer on each conductive pad at least partially, placing an alignment screen including layout positions for a plurality of thermoelectric legs, disposing a plurality of thermoelectric legs to the layout positions set by the alignment screen so that each pad is at least attached with two thermoelectric legs, removing the alignment screen after a drying process, providing a lead frame including a plurality of sheet conductors at least partially connected to each other, applying a second braze alloy layer over each of the plurality of sheet conductors, placing the lead frame with alignment onto the disposed plurality of thermoelectric legs, performing a brazing process to have the plurality of thermoelectric legs respectively bond to corresponding conductive pads through the first braze alloy layer and to corresponding sheet conductors through the second braze alloy layer.

According to yet another embodiment, a method for assembling a multi-leg package thermoelectric module includes providing an assembly base structure. The assembly base structure includes at least two alignment pins located on two corner regions. Additionally, the method includes placing an MLP substrate in the assembly base structure. The MLP substrate includes an array of conductive pads arranged in rows and columns separated each other by a spacing. Moreover, the method includes applying a braze alloy layer on each conductive pad at least partially, placing an alignment screen including layout positions for a plurality of thermoelectric legs, disposing a plurality of thermoelectric legs to the layout positions set by the alignment screen so that each pad is at least attached with two thermoelectric legs, and placing a precise weight member over the disposed plurality of thermoelectric legs. The precise weight member is aligned through the two alignment pins with the assembly base structure. Also, the method includes performing a brazing process to have the plurality of thermoelectric legs respectively bond to corresponding conductive pads through the braze alloy layer, removing the precise weight member and cleaning, providing a lead frame including a plurality of sheet conductors at least partially connected to each other, applying an eutectic alloy layer over each of the plurality of sheet conductors, disposing a lead frame over the plurality of thermoelectric legs with alignment through the two alignment pins, placing a precise ceramic weight member over the disposed lead frame, and applying a soldering process with a thermal profile within a forming gas to have each sheet conductor aligned to bond via the soldering alloy layer with four thermoelectric legs from two successive rows and two successive columns.

According to yet another embodiment, a method for assembling a multi-leg package thermoelectric module includes providing an assembly base structure. The assembly base structure includes at least two alignment pins located on two corner regions. Additionally, the method includes placing an MLP polyimide film in the assembly base structure. The MLP polyimide film includes an array of conductive pads arranged in rows and columns separated each other by a spacing. Moreover, the method includes applying a first eutectic solder layer on each conductive pad at least partially, placing an alignment screen including layout positions for a plurality of thermoelectric legs, disposing a plurality of thermoelectric legs to the layout positions set by the alignment screen so that each pad is at least attached with two thermoelectric legs, and placing a precise weight member over the disposed plurality of thermoelectric legs. The precise weight member is aligned through the two alignment pins with the assembly base structure. Also, the method includes performing a drying process, applying a first soldering process with a thermal profile within a forming gas to have each thermoelectric leg aligned to bond via the first eutectic alloy layer with a corresponding conductive pad, providing a lead frame including a plurality of sheet conductors at least partially connected to each other, and printing a second eutectic solder layer over a plurality of sheet conductors configured to match the positions of the plurality of thermoelectric legs. Additionally, the method includes placing the lead frame with alignment to have the second eutectic alloy layer on each sheet conductors in contact with four thermoelectric legs, placing a precise ceramic weight member over the lead frame, and applying a second soldering process containing a forming gas with a thermal profile to have each sheet conductor aligned to bond with the four thermoelectric legs.

According to yet another embodiment, a thermoelectric device with a multi-leg package includes a first ceramic base structure including a first surface and a second surface, and a first plurality of pads including one or more first materials thermally and electrically conductive. The first plurality of pads are attached to the first surface. Additionally, the thermoelectric device includes a second plurality of pads including the one or more first materials. The second plurality of pads are attached to the second surface and arranged in a mirror image with the first plurality of pads. Moreover, the thermoelectric device includes a plurality of thermoelectric legs attached to the first plurality of pads respectively. Each pad of the first plurality of pads is attached to at least two first thermoelectric legs of the plurality of thermoelectric legs. Also, the thermoelectric device includes a first plurality of sheet conductors attached to the plurality of thermoelectric legs respectively and including one or more second materials thermally and electrically conductive. Each sheet conductor of the first plurality of sheet conductors is attached to at least two second thermoelectric legs of the plurality of thermoelectric legs. The first plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs. For example, the thermoelectric device is implemented according to at least FIG. 9, FIG. 16, and/or FIG. 18.

In another example, the first plurality of sheet conductors are parts of a metal lead frame without any metal tab linking the first plurality of sheet conductors (e.g., implemented according to at least FIG. 9). In yet another example, the first plurality of sheet conductors are parts of a polyimide lead frame including a plurality of polyimide tabs linking the first plurality of sheet conductors (e.g., implemented according to at least FIG. 18). In yet another example, a thermoelectric device further includes a second ceramic base structure including a third surface and a fourth surface, and a second plurality of sheet conductors including the one or more second materials thermally and electrically conductive, the first plurality of sheet conductors being attached to the third surface, the second plurality of sheet conductors being attached to the fourth surface and arranged in a mirror image with the first plurality of sheet conductors (e.g., implemented according to at least FIG. 16).

According to yet another embodiment, a thermoelectric device with a multi-leg package includes a plurality of pads including one or more first materials thermally and electrically conductive. The plurality of pads are parts of a first metal lead frame without any metal tab linking the plurality of pads. Additionally, the thermoelectric device includes a plurality of thermoelectric legs attached to the plurality of pads respectively. Each pad of the plurality of pads is attached to at least two first thermoelectric legs of the plurality of thermoelectric legs. Moreover, thermoelectric device includes a first plurality of sheet conductors attached to the plurality of thermoelectric legs respectively and including one or more second materials thermally and electrically conductive. Each sheet conductor of the first plurality of sheet conductors is attached to at least two second thermoelectric legs of the plurality of thermoelectric legs. The plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs. For example, the thermoelectric device is implemented according to at least FIG. 17 and/or FIG. 19.

In another example, the first plurality of sheet conductors are parts of a second metal lead frame without any metal tab linking the first plurality of sheet conductors (e.g., implemented according to at least FIG. 17). In yet another example, the first plurality of sheet conductors are parts of a polyimide lead frame including a plurality of polyimide tabs linking the first plurality of sheet conductors (e.g., implemented according to at least FIG. 19).

According to yet another embodiment, a method for making a thermoelectric device with a multi-leg package includes providing a first ceramic base structure including a first surface and a second surface. The first surface is attached to a first plurality of pads, the second surface is attached to a second plurality of pads arranged in a mirror image with the first plurality of pads, and both the first plurality of pads and the second plurality of pads include one or more first materials thermally and electrically conductive. Additionally, the method includes attaching a plurality of thermoelectric legs to the first plurality of pads respectively. Each pad of the first plurality of pads is attached to at least two first thermoelectric legs of the plurality of thermoelectric legs. Additionally, the method includes attaching a first plurality of sheet conductors to the plurality of thermoelectric legs respectively. The first plurality of sheet conductors include one or more second materials thermally and electrically conductive, and each sheet conductor of the first plurality of sheet conductors is attached to at least two second thermoelectric legs of the plurality of thermoelectric legs. The first plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

For example, the method further includes providing the first plurality of sheet conductors as parts of a metal lead frame without any metal tab linking the first plurality of sheet conductors. In another example, the method further includes providing the first plurality of sheet conductors as parts of a polyimide lead frame including a plurality of polyimide tabs linking the first plurality of sheet conductors. In yet another example, the method further includes providing a second ceramic base structure including a third surface and a fourth surface. The third surface is attached to the first plurality of sheet conductors, the fourth surface is attached to a second plurality of sheet conductors arranged in a mirror image with the first plurality of sheet conductors, and both the first plurality of sheet conductors and the second plurality of sheet conductors include one or more second materials thermally and electrically conductive.

According to yet another embodiment, a method for making a thermoelectric device with a multi-leg package includes providing a plurality of pads including one or more first materials thermally and electrically conductive. The plurality of pads are parts of a first metal lead frame without any metal tab linking the plurality of pads. Additionally, the method includes attaching a plurality of thermoelectric legs to the plurality of pads respectively. Each pad of the plurality of pads is attached to at least two first thermoelectric legs of the plurality of thermoelectric legs. Moreover, the method includes attaching a first plurality of sheet conductors to the plurality of thermoelectric legs respectively and including one or more second materials thermally and electrically conductive. Each sheet conductor of the first plurality of sheet conductors is attached to at least two second thermoelectric legs of the plurality of thermoelectric legs. The plurality of pads include a first pad and a second pad configured to allow a first electrical current to flow between the first pad and the second pad only through two or more third thermoelectric legs of the plurality of thermoelectric legs, and the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

For example, the method further includes providing the first plurality of sheet conductors as parts of a second metal lead frame without any metal tab linking the first plurality of sheet conductors. In another example, the method further includes providing the first plurality of sheet conductors as parts of a polyimide lead frame including a plurality of polyimide tabs linking the first plurality of sheet conductors.

According to certain embodiments, a thermoelectric device needs to withstand large temperature gradients across its thickness in order to operate at high efficiencies and generate high power densities. For example, the thermoelectric device also needs to remain flat because the out-of-plane deflection can result in loss of thermal contact with the heat source and/or the heat sink and thus result in a loss of power production. In another example, a mismatch in thermal expansion created by the large temperature gradient can also cause high stress and potentially failure of the device parts.

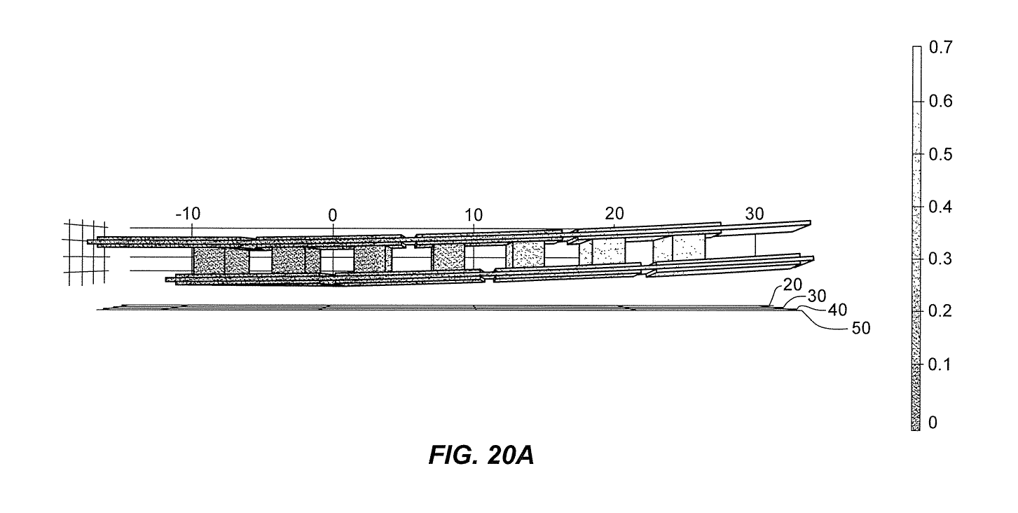

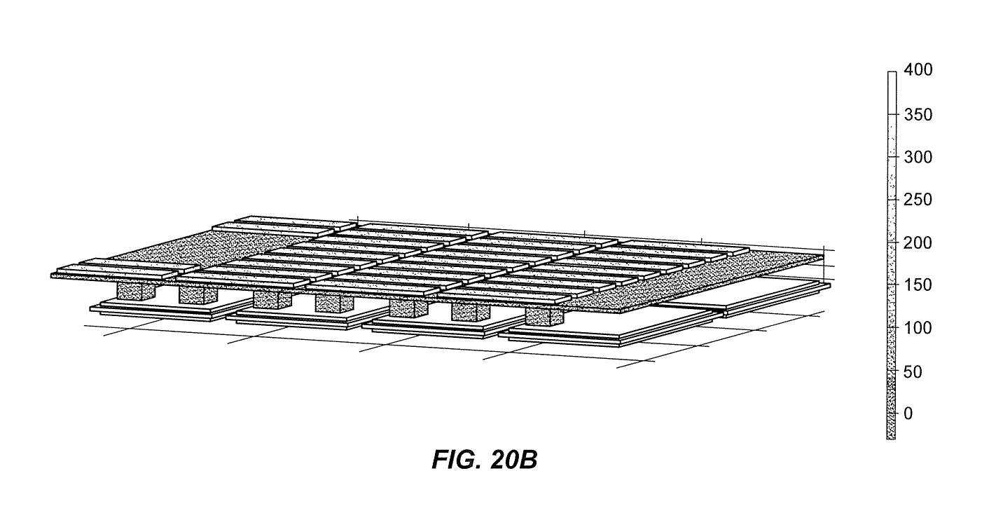

According to some embodiments, finite element stress analysis (FEA) has been conducted to quantify the reduction in thermally-induced stresses and to also quantify the reduction in thermally-induced deflections for certain device structures. In each of the six examples presented below, the device modeled is 40-mm-long by 40-mm-wide by 3-mm-thick, operating in a 500° C.-to-150° C. thermal gradient, and the simulations have used particular properties of selected thermoelectric and substrate materials. Also, for each of these six examples presented below, the simulations have been conducted using the COSMOS software, with results shown in FIGS. 20A-B, 21A-B, 22A-B and 23, wherein some deflections visible in these graphics have been exaggerated for illustrative purposes.

### Example 1

A conventional thermoelectric device includes two ceramic plates with a low coefficient of thermal expansion (CTE) (e.g., CTE being lower than 10×10⁻⁶/° C., such as CTE equal to 4×10⁻⁶/° C. at the room temperature). Additionally, the conventional thermoelectric device further includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are sandwiched between the two ceramic plates and bonded to the two ceramic plates via thin metal shunts (e.g., CTE of the thin metal shunts being equal to 16×10⁻⁶/° C. at the room temperature) for electrical connection of the legs.

FIGS. 20A and 20B are simplified diagrams showing simulation results of the conventional thermoelectric device for Example 1. As shown in FIG. 20A, the unconstrained out-of-plane deflections of the 40-mm-wide device has a peak out-of-plane deflection of 0.7 mm. The Von Mises stress profiles of this conventional thermoelectric device are shown in FIG. 20B. Both deflections and stresses as shown in FIGS. 20A and 20B are caused by the fact that the hot side of the thermoelectric device is at higher temperature than the cold side and thus experiences greater thermal expansion, and this differential expansion cannot be effectively accommodated by two rigid ceramic plates according to some embodiments.

For each of Examples 1-6, Table 1 presents peak Von Mises stresses in each of certain components and in each joint between some of these components according to certain embodiments. As shown in Table 1, for Example 1, the peak stresses in all components are very high, particularly in the thermoelectric legs, which often are the weakest component, thus likely to cause mechanical failure of the thermoelectric device.

TABLE 1

| | | | Peak Von Mises Stresses (Mpa) | | | | |
|---|---|---|---|---|---|---|---|
| Example | Hot-Side | Cold-Side | Hot-Side | Hot-Side | Thermoelectric | Cold-Side | Cold-Side |
| No. | Substrate | Substrate | Substrate | Joint | Legs | Joint | Substrate |
| 1 | Low-CTE | Low-CTE | 418 | 340 | 280 | 210 | 360 |
| | Ceramic Plate | Ceramic Plate | | | | | |
| 2 | Low-CTE | Unconstrained | 320 | 186 | 140 | 32 | 24 |
| | Ceramic Plate | Thin Metal | | | | | |
| | | Shunts | | | | | |
| 3 | Low-CTE | Polyimide | 320 | 186 | 140 | 32 | 24 |
| | Ceramic Plate | Plate | | | | | |
| 4 | Low-CTE | High-CTE | 320 | 186 | 140 | 74 | 160 |
| | Ceramic Plate | Ceramic Plate | | | | | |
| 5 | Unconstrained | Unconstrained | 36 | 24 | 6 | 6 | 11 |
| | Thin Metal | Thin Metal | | | | | |
| | Shunts | Shunts | | | | | |
| 6 | Unconstrained | Polyimide | 36 | 24 | 6 | 6 | 11 |
| | Thin Metal | Plate | | | | | |
| | Shunts | | | | | | |

### Example 2

According to one embodiment of the present invention, one side of a thermoelectric device is made flexible in order to reduce stresses and deflections, so a thermoelectric device includes only one, not two, ceramic plate with a low coefficient of thermal expansion (CTE) (e.g., CTE being lower than 10×10⁻⁶/° C., such as CTE equal to 4×10⁻⁶/° C. at the room temperature). Additionally, the thermoelectric device further includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are, on one side, in contact with some thin metal shunts (e.g., CTE of the thin metal shunts being equal to 16×10⁻⁶/° C. at the room temperature), and on the other side, bonded to the ceramic plate via other thin metal shunts (e.g., CTE of the thin metal shunts being equal to 16×10⁻⁶/° C. at the room temperature). For example, on the side without the ceramic plate, movement between the thin metal shunts is not constrained.

### Example 3

According to another embodiment of the present invention, one side of a thermoelectric device is made flexible in order to reduce stresses and deflections, so a thermoelectric device includes one ceramic plate with a low coefficient of thermal expansion (CTE) (e.g., CTE being lower than 10×10⁻⁶/° C., such as CTE equal to 4×10⁻⁶/° C. at the room temperature) and one flexible plate (e.g., a polyimide plate with CTE equal to 20×10⁻⁶/° C.), instead of two ceramic plates. Additionally, thermoelectric device further includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are, on one side, bonded to the ceramic plate via some thin metal shunts (e.g., CTE of the thin metal shunts being equal to 16×10⁻⁶/° C. at the room temperature), and on the other side, bonded to the flexible plate via other thin metal shunts (e.g., CTE of the thin metal shunts being equal to 16×10⁻⁶/° C. at the room temperature). In another example, the polyimide plate is made of Kapton.

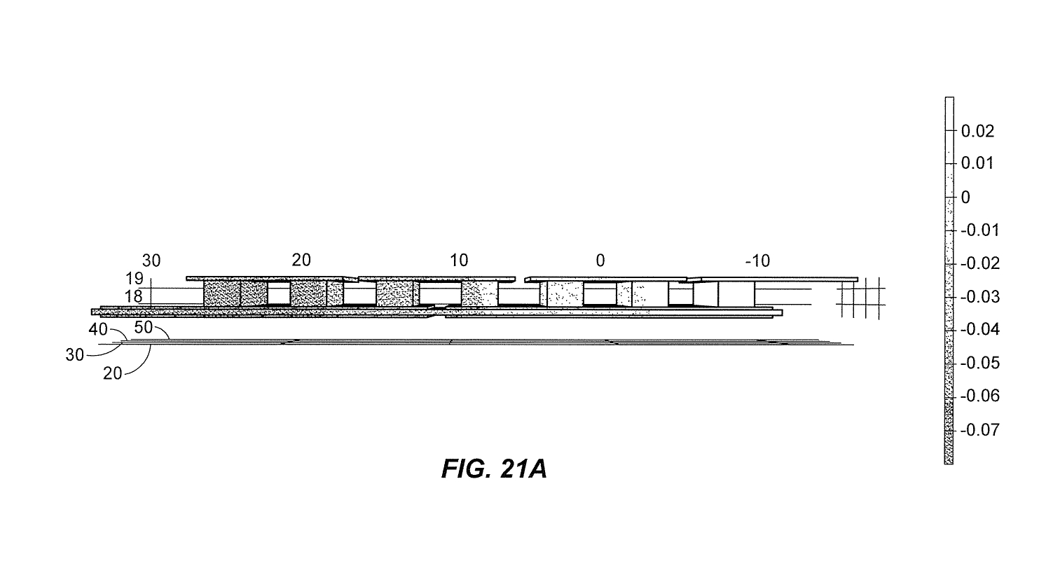

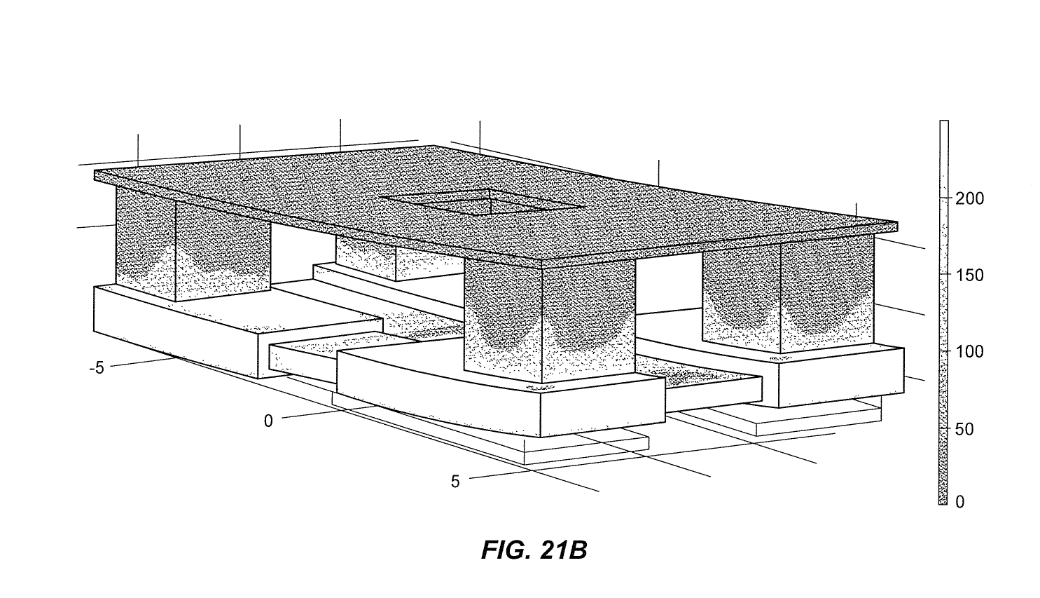

FIGS. 21A and 21B are simplified diagrams showing simulation results of thermoelectric devices for Examples 2 and 3 according to some embodiments of the present invention. These diagrams are merely examples, which should not unduly limit the scope of the claims. One of ordinary skill in the art would recognize many variations, alternatives, and modifications. FIG. 21A shows the unconstrained out-of-plane deflections, and FIG. 20B shows the Von Mises stress profiles. As shown in FIG. 21A, the unconstrained out-of-plane deflections of the 40-mm-wide device has a peak out-of-plane deflection of 0.07 mm. Additionally, for Examples 2 and 3, the peak Von Mises stresses are shown in Table 1 according to certain embodiments.

### Example 4

According to one embodiment of the present invention, one side of a thermoelectric device, even though remaining rigid, is made of a material with a high coefficient of thermal expansion (CTE), in order to reduce stresses and deflections, so a thermoelectric device includes one ceramic plate with a low coefficient of thermal expansion (CTE) (e.g., CTE being lower than 10×10⁻⁶/° C., such as CTE equal to 4×10⁻⁶/° C. at the room temperature), and one ceramic plate with a high coefficient of thermal expansion (CTE) (e.g., CTE being higher than 10×10⁻⁶/° C., such as CTE equal to 11×10⁻⁶/° C. at the room temperature). Additionally, the thermoelectric device further includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are, on one side, bonded to the low-CTE ceramic plate via some thin metal shunts (e.g., CTE of the thin metal shunts being equal to 16×10⁻⁶/° C. at the room temperature), and on the other side, bonded to the high-CTE ceramic plate via other thin metal shunts (e.g., CTE of the thin metal shunts being equal to 16×10⁻⁶/° C. at the room temperature). For example, the low-CTE ceramic plate is placed on the hot side and the high-CTE ceramic plate is placed on the cold side, so that the difference in thermal expansion between the hot side and the cold side due to the thermal gradient is reduced.

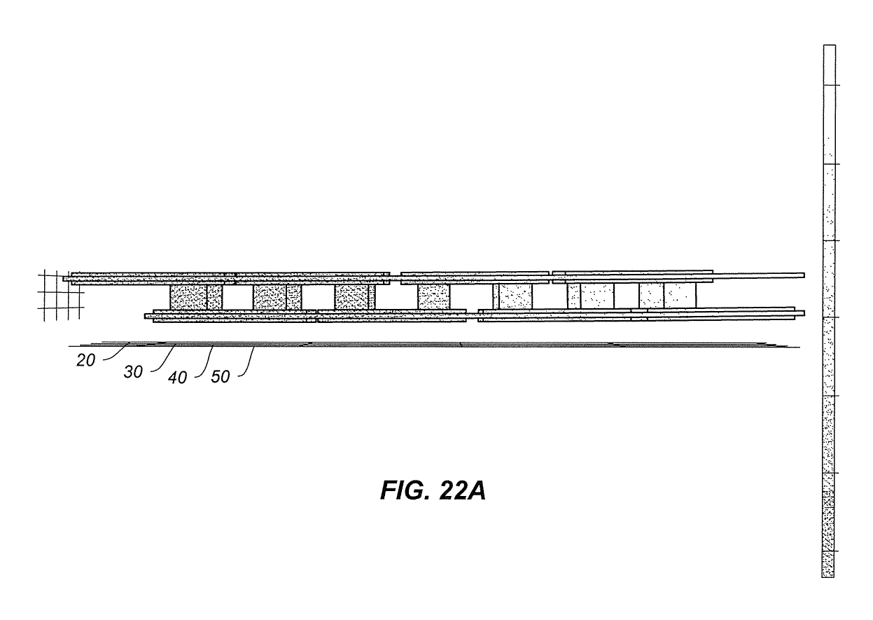

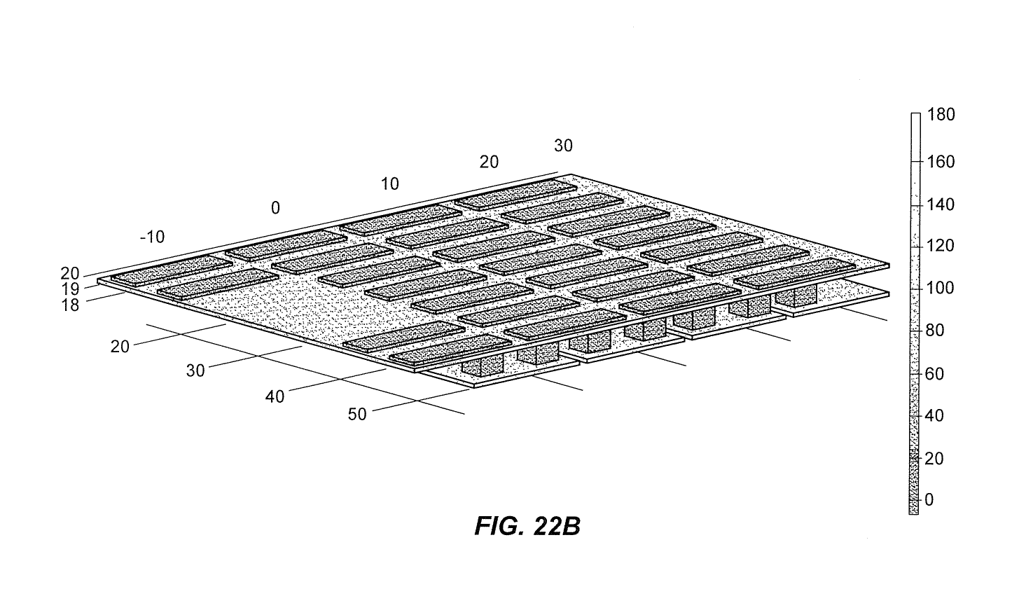

FIGS. 22A and 22B are simplified diagrams showing simulation results of the thermoelectric device for Example 4 according to one embodiment of the present invention. These diagrams are merely examples, which should not unduly limit the scope of the claims. One of ordinary skill in the art would recognize many variations, alternatives, and modifications. FIG. 22A shows the unconstrained out-of-plane deflections, and FIG. 22B shows the Von Mises stress profiles. As shown in FIG. 22A, the unconstrained out-of-plane deflections of the 40-mm-wide device has a peak out-of-plane deflection of 0.3 mm. Additionally, for Example 4, the peak Von Mises stresses are shown in Table 1 according to one embodiment.

### Example 5

According to one embodiment of the present invention, both sides of a thermoelectric device are made flexible in order to reduce stresses and deflections, so a thermoelectric device does not include any ceramic plate, but does include thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are in contact with some thin metal shunts (e.g., CTE of the thin metal shunts being equal to 16×10⁻⁶/° C. at the room temperature) on one side, and in contact with other thin metal shunts (e.g., CTE of the thin metal shunts being equal to 16×10⁻⁶/° C. at the room temperature) on the other side. For example, on either side, movement between the thin metal shunts is not constrained

### Example 6

According to another embodiments of the present invention, both sides of a thermoelectric device are made flexible in order to reduce stresses and deflections, so a thermoelectric device does not include any rigid ceramic plate, but does include one flexible plate (e.g., a polyimide plate with CTE equal to 20×10⁻⁶/° C.). Additionally, the thermoelectric device further includes thermoelectric legs made of a thermoelectric material with a high coefficient of thermal expansion (e.g., CTE being higher than 10×10⁻⁶/° C., such as CTE equal to 11×10⁻⁶/° C. at the room temperature for n-type legs and CTE equal to 14×10⁻⁶/° C. at the room temperature for p-type legs), wherein the thermoelectric legs are, on one side, in contact with some thin metal shunts (e.g., CTE of the thin metal shunts being equal to 16×10⁻⁶/° C. at the room temperature), and on the other side, bonded to the flexible plate via other thin metal shunts (e.g., CTE of the thin metal shunts being equal to 16×10⁻⁶/° C. at the room temperature). In another example, the polyimide plate is made of Kapton.

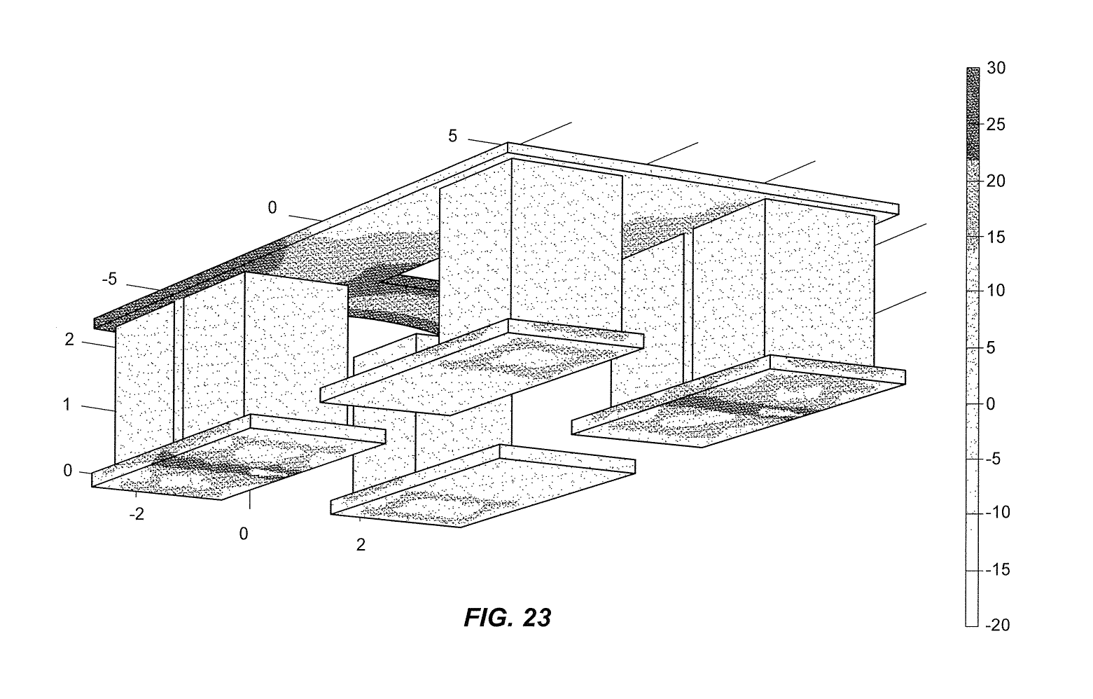

FIG. 23 is a simplified diagram showing simulation results of thermoelectric devices for Examples 5 and 6 according to some embodiments of the present invention. This diagram is merely an example, which should not unduly limit the scope of the claims. One of ordinary skill in the art would recognize many variations, alternatives, and modifications. FIG. 23 shows the Von Mises stress profiles for Examples 5 and 6. Additionally, for Examples 5 and 6, the peak Von Mises stresses are shown in Table 1 according to certain embodiments. Moreover, for Examples 5 and 6, the unconstrained out-of-plane deflections of the 40-mm-wide device have a peak out-of-plane deflection less than 0.025 mm (e.g., the peak out-of-plane deflection equal to zero).

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A thermoelectric device with a multi-leg package, the device comprising:
a first ceramic base structure including a first surface and a second surface;
a first plurality of pads including one or more first materials thermally and electrically conductive, the first plurality of pads being attached to the first surface;
a second plurality of pads including the one or more first materials, the second plurality of pads being attached to the second surface and arranged in a mirror image with the first plurality of pads;
a plurality of thermoelectric legs attached to the first plurality of pads respectively, each pad of the first plurality of pads being attached to at least two first thermoelectric legs of the plurality of thermoelectric legs; and
a first plurality of sheet conductors attached to the plurality of thermoelectric legs respectively and including one or more second materials thermally and electrically conductive, each sheet conductor of the first plurality of sheet conductors being attached to at least two second thermoelectric legs of the plurality of thermoelectric legs;
wherein:
the first plurality of pads include a first pad and a second pad configured to allow a first electrical current to flow between the first pad and the second pad only through two or more third thermoelectric legs of the plurality of thermoelectric legs; and
the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

2. The thermoelectric device of claim 1 wherein the first plurality of pads are attached to the first surface through one or more third materials.

3. The thermoelectric device of claim 1 wherein the second plurality of pads are attached to the second surface through one or more third materials.

4. The thermoelectric device of claim 1 wherein the plurality of thermoelectric legs are attached to the first plurality of pads through one or more third materials.

5. The thermoelectric device of claim 1 wherein the two first thermoelectric legs include one thermoelectric leg doped to n-type and one thermoelectric leg doped to p-type.

6. The thermoelectric device of claim 1 wherein the first plurality of sheet conductors are attached to the plurality of thermoelectric legs through one or more third materials.

7. The thermoelectric device of claim 1 wherein the two second thermoelectric legs include one thermoelectric leg doped to n-type and one thermoelectric leg doped to p-type.

8. The thermoelectric device of claim 1 wherein one of the two first thermoelectric legs and one of the two second thermoelectric legs are the same leg.

9. The thermoelectric device of claim 1 wherein the two or more third thermoelectric legs include one thermoelectric leg doped to n-type and one thermoelectric leg doped to p-type.

10. The thermoelectric device of claim 1 wherein the two or more fourth thermoelectric legs include one thermoelectric leg doped to n-type and one thermoelectric leg doped to p-type.

11. The thermoelectric device of claim 1 wherein one of the two or more third thermoelectric legs and one of the two or more fourth thermoelectric legs are the same leg.

12. The thermoelectric device of claim 11 wherein the first electrical current and the second electrical current are configured to flow through the same leg as the same current.

13. The device of claim 1 wherein the first plurality of sheet conductors are parts of a metal lead frame without any metal tab linking the first plurality of sheet conductors.

14. The thermoelectric device of claim 13, and further comprising:
a first plate attached to the second plurality of pads; and
a second plate attached to the first plurality of sheet conductors.

15. The thermoelectric device of claim 14 wherein:
the first plate is attached to the second plurality of pads through the first thermal interface layer; and
the second plate is attached to the first plurality of sheet conductors through the second thermal interface layer.

16. The device of claim 1 wherein the first plurality of sheet conductors are parts of a polyimide lead frame including a plurality of polyimide tabs linking the first plurality of sheet conductors.

17. The device of claim 16 wherein the polyimide lead frame is configured to tolerate a temperature of the first ceramic base structure higher than 250° C.

18. The thermoelectric device of claim 16, and further comprising:
a first plate attached to the second plurality of pads; and
a second plate attached to the first plurality of sheet conductors.

19. The thermoelectric device of claim 18 wherein:
the first plate is attached to the second plurality of pads through the first thermal interface layer; and
the second plate is attached to the first plurality of sheet conductors through the second thermal interface layer.

20. The device of claim 1, and further comprising:
a second ceramic base structure including a third surface and a fourth surface, the first plurality of sheet conductors being attached to the third surface; and
a second plurality of sheet conductors including the one or more second materials thermally and electrically conductive, the second plurality of sheet conductors being attached to the fourth surface and arranged in a mirror image with the first plurality of sheet conductors.

21. The device of claim 20 wherein the first plurality of sheet conductors are attached to the third surface through one or more third materials.

22. The device of claim 20 wherein the second plurality of sheet conductors are attached to the fourth surface through one or more third materials.

23. The thermoelectric device of claim 20, and further comprising:
a first plate attached to the second plurality of pads; and
a second plate attached to the second plurality of sheet conductors.

24. The thermoelectric device of claim 23 wherein:
the first plate is attached to the second plurality of pads through the first thermal interface layer; and
the second plate is attached to the second plurality of sheet conductors through the second thermal interface layer.

25. A thermoelectric device with a multi-leg package, the device comprising:
a plurality of pads including one or more first materials thermally and electrically conductive, the plurality of pads being parts of a first metal lead frame without any metal tab linking the plurality of pads;
a plurality of thermoelectric legs attached to the plurality of pads respectively, each pad of the plurality of pads being attached to at least two first thermoelectric legs of the plurality of thermoelectric legs; and
a first plurality of sheet conductors attached to the plurality of thermoelectric legs respectively and including one or more second materials thermally and electrically conductive, each sheet conductor of the first plurality of sheet conductors being attached to at least two second thermoelectric legs of the plurality of thermoelectric legs;
wherein:
the plurality of pads include a first pad and a second pad configured to allow a first electrical current to flow between the first pad and the second pad only through two or more third thermoelectric legs of the plurality of thermoelectric legs; and
the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

26. The thermoelectric device of claim 25 wherein the plurality of thermoelectric legs are attached to the plurality of pads through one or more third materials.

27. The thermoelectric device of claim 25 wherein the two first thermoelectric legs include one thermoelectric leg doped to n-type and one thermoelectric leg doped to p-type.

28. The thermoelectric device of claim 25 wherein the first plurality of sheet conductors are attached to the plurality of thermoelectric legs through one or more third materials.

29. The thermoelectric device of claim 25 wherein the two second thermoelectric legs include one thermoelectric leg doped to n-type and one thermoelectric leg doped to p-type.

30. The thermoelectric device of claim 25 wherein one of the two first thermoelectric legs and one of the two second thermoelectric legs are the same leg.

31. The thermoelectric device of claim 25 wherein the two or more third thermoelectric legs include one thermoelectric leg doped to n-type and one thermoelectric leg doped to p-type.

32. The thermoelectric device of claim 25 wherein the two or more fourth thermoelectric legs include one thermoelectric leg doped to n-type and one thermoelectric leg doped to p-type.

33. The thermoelectric device of claim 25 wherein one of the two or more third thermoelectric legs and one of the two or more fourth thermoelectric legs are the same leg.

34. The thermoelectric device of claim 33 wherein the first electrical current and the second electrical current are configured to flow through the same leg as the same current.

35. The device of claim 25 wherein the first plurality of sheet conductors are parts of a second metal lead frame without any metal tab linking the first plurality of sheet conductors.

36. The device of claim 25 wherein the first plurality of sheet conductors are parts of a polyimide lead frame including a plurality of polyimide tabs linking the first plurality of sheet conductors.

37. The device of claim 36 wherein the polyimide lead frame is configured to tolerate a temperature of the plurality of pads higher than 250° C.

38. The thermoelectric device of claim 25, and further comprising:
a first plate attached to the second plurality of pads; and
a second plate attached to the first plurality of sheet conductors.

39. The thermoelectric device of claim 38 wherein:
the first plate is attached to the second plurality of pads through the first thermal interface layer; and
the second plate is attached to the first plurality of sheet conductors through the second thermal interface layer.

40. A method for making a thermoelectric device with a multi-leg package, the method comprising:
providing a first ceramic base structure including a first surface and a second surface, the first surface being attached to a first plurality of pads, the second surface being attached to a second plurality of pads arranged in a mirror image with the first plurality of pads, both the first plurality of pads and the second plurality of pads including one or more first materials thermally and electrically conductive;
attaching a plurality of thermoelectric legs to the first plurality of pads respectively, each pad of the first plurality of pads being attached to at least two first thermoelectric legs of the plurality of thermoelectric legs; and
attaching a first plurality of sheet conductors to the plurality of thermoelectric legs respectively, the first plurality of sheet conductors including one or more second materials thermally and electrically conductive, each sheet conductor of the first plurality of sheet conductors being attached to at least two second thermoelectric legs of the plurality of thermoelectric legs;
wherein:
the first plurality of pads include a first pad and a second pad configured to allow a first electrical current to flow between the first pad and the second pad only through two or more third thermoelectric legs of the plurality of thermoelectric legs; and
the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

41. The method of claim 40, and further comprising providing the first plurality of sheet conductors as parts of a metal lead frame without any metal tab linking the first plurality of sheet conductors.

42. The method of claim 40, and further comprising providing the first plurality of sheet conductors as parts of a polyimide lead frame including a plurality of polyimide tabs linking the first plurality of sheet conductors.

43. The method of claim 40, and further comprising providing a second ceramic base structure including a third surface and a fourth surface, the third surface being attached to the first plurality of sheet conductors, the fourth surface being attached to a second plurality of sheet conductors arranged in a mirror image with the first plurality of sheet conductors, both the first plurality of sheet conductors and the second plurality of sheet conductors including one or more second materials thermally and electrically conductive.

44. A method for making a thermoelectric device with a multi-leg package, the method device comprising:
providing a plurality of pads including one or more first materials thermally and electrically conductive, the plurality of pads being parts of a first metal lead frame without any metal tab linking the plurality of pads;
attaching a plurality of thermoelectric legs to the plurality of pads respectively, each pad of the plurality of pads being attached to at least two first thermoelectric legs of the plurality of thermoelectric legs; and
attaching a first plurality of sheet conductors to the plurality of thermoelectric legs respectively and including one or more second materials thermally and electrically conductive, each sheet conductor of the first plurality of sheet conductors being attached to at least two second thermoelectric legs of the plurality of thermoelectric legs;
wherein:
the plurality of pads include a first pad and a second pad configured to allow a first electrical current to flow between the first pad and the second pad only through two or more third thermoelectric legs of the plurality of thermoelectric legs; and
the first plurality of sheet conductors include a first sheet conductor and a second sheet conductor configured to allow a second electrical current to flow between the first sheet conductor and the second sheet conductor only through two or more fourth thermoelectric legs of the plurality of thermoelectric legs.

45. The method of claim 44, and further comprising providing the first plurality of sheet conductors as parts of a second metal lead frame without any metal tab linking the first plurality of sheet conductors.

46. The method of claim 44, and further comprising providing the first plurality of sheet conductors as parts of a polyimide lead frame including a plurality of polyimide tabs linking the first plurality of sheet conductors.
